(19) United States
(12) Patent Application Publication
(10) Pub. No.: US 2024/0120384 A1
(43) Pub. Date: Apr. 11, 2024

(54) SIC SEMICONDUCTOR DEVICE

(71) Applicant: ROHM CO., LTD., Kyoto-shi, Kyoto (JP)

(72) Inventors: Kenji YAMAMOTO, Kyoto-shi, Kyoto (JP); Yuki NAKANO, Kyoto-shi, Kyoto (JP)

(73) Assignee: ROHM CO., LTD., Kyoto-shi, Kyoto (JP)

(21) Appl. No.: 18/267,109

(22) PCT Filed: Nov. 18, 2021
(86) PCT No.: PCT/JP2021/042490

§ 371 Date: Jun. 14, 2023

(30) Foreign Application Priority Data
Feb. 1, 2021 (JP) 2021-014602

(51) Int. Cl. H01L 29/10; H01L 29/16; H01L 29/36

(52) U.S. Cl. CPC H01L 29/1095; H01L 29/1608; H01L 29/36; H01L 29/872

(57) ABSTRACT

An SiC semiconductor device includes an SiC chip that has a main surface, and an n-type drift region that is formed in a surface layer portion of the main surface and has an impurity concentration adjusted by at least two types of pentavalent elements.

### TECHNICAL FIELD

The present application corresponds to Japanese Patent Application No. 2021-014602 filed on Feb. 1, 2021 in the Japan Patent Office, and the entire disclosure of this applications is incorporated herein by reference. The present invention relates to an SiC semiconductor device.

### BACKGROUND ART

Patent Literature 1 discloses an SiC-SBD that includes an SiC substrate, and an SiC epitaxial layer that is formed on the SiC substrate. Patent Literature 2 discloses a semiconductor device that includes an SiC substrate, and an n-type drift region and a p-type pillar region that are formed alternately in a vertical direction with respect to a thickness direction of the SiC substrate, on the SiC substrate.

### CITATION LIST

### Patent Literature

Patent Literature 1: United States Patent Application No. 2008/0237608 Specification
Patent Literature 2: United States Patent Application No. 2019/0148485 Specification

### SUMMARY OF INVENTION

### Technical Problem

A preferred embodiment of the present invention provides an SiC semiconductor device that is capable of improving electrical characteristics.

### Solution to Problem

A preferred embodiment provides an SiC semiconductor device including an SiC chip that has a main surface, and an n-type drift region that is formed in a surface layer portion of the main surface and has an impurity concentration adjusted by at least two types of pentavalent elements.

A preferred embodiment provides an SiC semiconductor device including an SiC chip that has a main surface, and a p-type drift region that is formed in a surface layer portion of the main surface and has an impurity concentration adjusted by a trivalent element other than boron.

A preferred embodiment provides an SiC semiconductor device including an SiC chip that has a main surface, an n-type drift region that is formed in a surface layer portion of the main surface and has an impurity concentration adjusted by at least two types of pentavalent elements, and a p-type impurity region that is formed inside the drift region such as to form a pn-junction portion with the drift region.

A preferred embodiment provides an SiC semiconductor device including an SiC chip that has a main surface, an n-type drift region that is formed in a surface layer portion of the main surface, and p-type impurity region that is formed inside the drift region such as to form a pn-junction portion with the drift region and has an impurity concentration adjusted by a trivalent element other than boron.

A preferred embodiment provides an SiC semiconductor device including an SiC chip that has a main surface, a p-type drift region that is formed in a surface layer portion of the main surface and has an impurity concentration adjusted by a trivalent element other than boron, and an n-type impurity region that is formed inside the drift region such as to form a pn-junction portion with the drift region and has an impurity concentration adjusted by a pentavalent element other than phosphorus and nitrogen.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a plan view of an SiC semiconductor device according to a first preferred embodiment.

FIG. 2 is a sectional view taken along line II-II shown in FIG. 1.

FIG. 3 is a graph of impurity concentration inside an SiC chip shown in FIG. 2.

FIG. 4A is a sectional view of a method for manufacturing the SiC semiconductor device shown in FIG. 1.

FIG. 4B is a sectional view of a step subsequent to that of FIG. 4A.

FIG. 4C is a sectional view of a step subsequent to that of FIG. 4B.

FIG. 4D is a sectional view of a step subsequent to that of FIG. 4C.

FIG. 5 is a sectional view for specifically describing the step of FIG. 4D.

FIG. 6 corresponds to FIG. 2 and is a sectional view of an SiC semiconductor device according to a second preferred embodiment.

FIG. 7 is a graph of impurity concentration inside an SiC chip shown in FIG. 6.

FIG. 8A is a sectional view of a method for manufacturing the SiC semiconductor device shown in FIG. 6.

FIG. 8B is a sectional view of a step subsequent to that of FIG. 8A.

FIG. 9 corresponds to FIG. 2 and is a sectional view of an SiC semiconductor device according to a third preferred embodiment.

FIG. 10 is a graph of impurity concentration inside an SiC chip shown in FIG. 9.

FIG. 11 corresponds to FIG. 9 and is a sectional view of an SiC semiconductor device according to a fourth preferred embodiment.

FIG. 12 is a graph of impurity concentration inside an SiC chip shown in FIG. 11.

FIG. 13 corresponds to FIG. 2 and is a sectional view of an SiC semiconductor device according to a fifth preferred embodiment.

FIG. 14 corresponds to FIG. 2 and is a sectional view of an SiC semiconductor device according to a sixth preferred embodiment.

FIG. 15 corresponds to FIG. 2 and is a sectional view of an SiC semiconductor device according to a seventh preferred embodiment.

FIG. 16 corresponds to FIG. 2 and is a sectional view of an SiC semiconductor device according to an eighth preferred embodiment.

FIG. 17 is a plan view of an SiC semiconductor device according to a ninth preferred embodiment.

FIG. 18 is a sectional view taken along line XVIII-XVIII shown in FIG. 17.

FIG. 19A is a sectional view of a method for manufacturing the SiC semiconductor device shown in FIG. 17.

FIG. 19B is a sectional view of a step subsequent to that of FIG. 19A.

FIG. 20 corresponds to FIG. 18 and is a sectional view of an SiC semiconductor device according to a tenth preferred embodiment.

FIG. 21A is a sectional view of a method for manufacturing the SiC semiconductor device shown in FIG. 20.

FIG. 21B is a sectional view of a step subsequent to that of FIG. 21A.

FIG. 22 corresponds to FIG. 18 and is a sectional view of an SiC semiconductor device according to an eleventh preferred embodiment.

FIG. 23 corresponds to FIG. 18 and is a sectional view of an SiC semiconductor device according to a twelfth preferred embodiment.

FIG. 24 is a plan view of a structure with which a functional device according to a first configuration example is applied to the SiC semiconductor device according to the first preferred embodiment.

FIG. 25 is a sectional view taken along line XXV-XXV shown in FIG. 24.

FIG. 26 is a plan view of an SiC chip shown in FIG. 25.

FIG. 27 is a plan view of a structure with which a functional device according to a second configuration example is applied to the SiC semiconductor device according to the tenth preferred embodiment.

FIG. 28 is a sectional view taken along line XXVIII-XXVIII shown in FIG. 27.

FIG. 29 is a plan view of an SiC chip shown in FIG. 28.

FIG. 30 is a plan view of a structure with which a functional device according to a third configuration example is applied to the SiC semiconductor device according to the first preferred embodiment.

FIG. 31 is a sectional view taken along line XXXI-XXXI shown in FIG. 30.

FIG. 32 is an enlarged view of a region XXXII shown in FIG. 30.

FIG. 33 is a sectional view taken along line XXXII-XXXII shown in FIG. 32.

FIG. 34 is an enlarged view of a region XXXIV shown in FIG. 31.

FIG. 35 is a plan view of a structure with which a functional device according to a fourth configuration example is applied to the SiC semiconductor device according to the tenth preferred embodiment.

FIG. 36 is an enlarged view of a region XXXVI shown in FIG. 35.

FIG. 37 is a sectional view taken along line XXXVII-XXXVII shown in FIG. 36.

FIG. 38 is a sectional view of a structure with which a functional device according to a fifth configuration example is applied to the SiC semiconductor device according to the tenth preferred embodiment.

### DESCRIPTION OF EMBODIMENTS

The attached drawings are not drawn precisely but are schematic views and are not necessarily matched in scale, etc. In the attached drawings, in order to clarify the structure of each semiconductor region, in addition to the conductivity type (n-type or p-type) of each semiconductor region, the element (element symbol) constituting the conductivity type is indicated together in parenthesis. The wording “substantially equal” and the wording “substantially constant” in this Description encompass cases where a numerical value of a measured object (measured location) is completely matched with a numerical value of a compared object (compared location) as well as cases where a numerical value of a measured object (measured location) falls within a range of not less than 0.9 times to not more than 1.1 times a numerical value of a compared object (compared location).

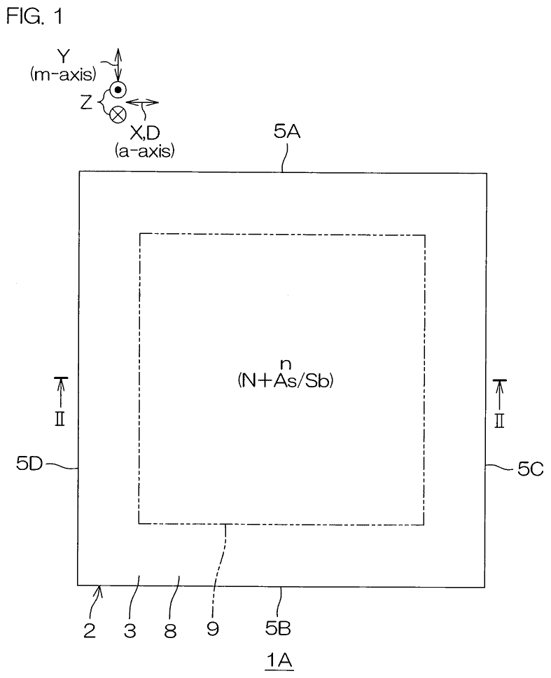

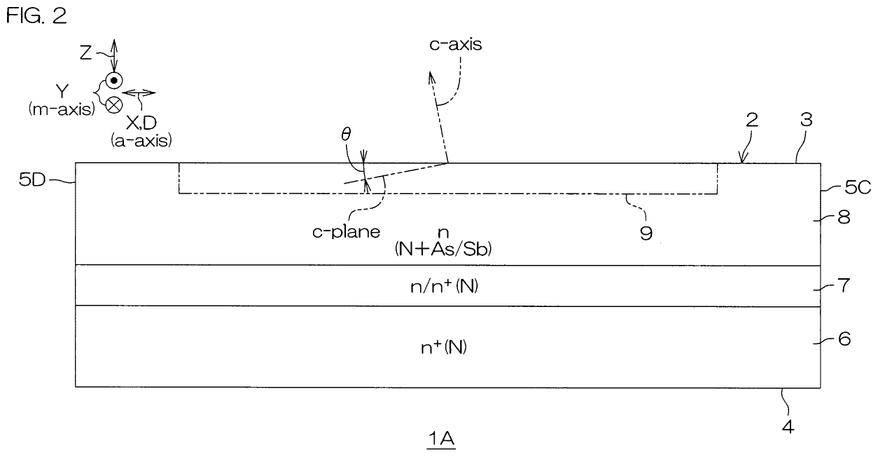

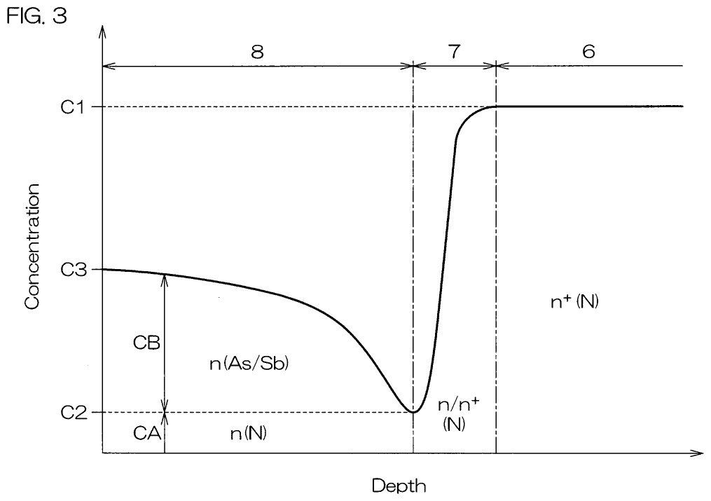

FIG. 1 is a plan view of an SiC semiconductor device 1A according to a first preferred embodiment. FIG. 2 is a sectional view taken along line II-II shown in FIG. 1. FIG. 3 is a graph of impurity concentration inside an SiC chip 2 shown in FIG. 2. In FIG. 3, the ordinate indicates the impurity concentration and the abscissa indicates depth.

Referring to FIG. 1 and FIG. 2, the SiC semiconductor device 1A includes the SiC chip 2 that is formed to a rectangular parallelepiped shape. The SiC chip 2 may be referred to as a “chip” or as a “semiconductor chip.” In this embodiment, the SiC chip 2 is constituted of an SiC (silicon carbide) monocrystal that is a hexagonal crystal. The SiC monocrystal that is a hexagonal crystal has a plurality of polytypes including a 2H (hexagonal)-SiC monocrystal, a 4H-SiC monocrystal, a 6H-SiC monocrystal, etc. Although with this embodiment, an example where the SiC chip 2 is constituted of a 4H-SiC monocrystal is illustrated, this does not exclude other polytypes.

The SiC chip 2 has a first main surface 3 at one side, a second main surface 4 at another side, and first to fourth side surfaces 5A to 5D connecting the first main surface 3 and the second main surface 4. The first main surface 3 and the second main surface 4 are formed to quadrilateral shapes in a plan view as viewed in a normal direction Z thereto (hereinafter referred to simply as “plan view”). The first main surface 3 and the second main surface 4 may be formed to square shapes or rectangular shapes in plan view.

The first main surface 3 and the second main surface 4 are respectively arranged along c-planes ((0001) planes) of the SiC monocrystal. Preferably, the first main surface 3 is formed by a silicon plane of the SiC monocrystal and the second main surface 4 is formed by a carbon plane of the SiC monocrystal. The first main surface 3 and the second main surface 4 have an off angle θ inclined at a predetermined angle in an off direction D with respect to the c-planes. The off direction D is preferably an a-axis direction ([11-20] direction) of the SiC monocrystal. The off angle θ may exceed 0° and be not more than 10°. The off angle θ is preferably not more than 5°. The off angle θ is especially preferably not less than 2° and not more than 4.5°.

The first side surface 5A and the second side surface 5B extend in a first direction X along the first main surface 3 and oppose each other in a second direction Y intersecting (specifically, orthogonal to) the first direction X. The third side surface 5C and the fourth side surface 5D extend in the second direction Y and oppose each other in the first direction X. In this embodiment, the first direction X is the a-axis direction ([11-20] direction) of the SiC monocrystal and the second direction Y is an m-axis direction ([1-100] direction) of the SiC monocrystal. The first direction X is thus the off direction D.

The SiC semiconductor device 1A includes an n-type base region 6 that is formed in a region inside the SiC chip 2 at the second main surface 4 side (surface layer portion of the second main surface 4). The base region 6 is formed as a layer that extends along the second main surface 4 and is exposed from the second main surface 4 and the first to fourth side surfaces 5A to 5D. The base region 6 has an impurity concentration that is adjusted by a first impurity (=n-type impurity) constituted of a pentavalent element. The first impurity is preferably constituted of one type of pentavalent element. The first impurity may be any one pentavalent element among phosphorus (P), nitrogen (N), arsenic (As), and antimony (Sb). The first impurity is preferably a pentavalent element other than phosphorus. In this embodiment, the first impurity is nitrogen.

Referring to FIG. 3, the base region 6 has a first concentration C1 that is substantially constant in a thickness direction. The first concentration C1 may be not less than 1×101⁸ cm⁻³ and not more than 1×10²¹ cm⁻³. The base region 6 may have a thickness not less than 5 μm and not more than 300 μm. The thickness of the base region 6 is preferably not less than 50 μm and not more than 250 μm. In this embodiment, the base region 6 is formed in an SiC substrate.

The SiC semiconductor device 1A includes an n-type buffer region 7 that is formed in a region inside the SiC chip 2 at the first main surface 3 side with respect to the base region 6. The buffer region 7 is formed in a thickness direction intermediate portion of the SiC chip 2 that is separated to the second main surface 4 side from the first main surface 3. The buffer region 7 is formed as a layer that extends along the first main surface 3 and is exposed from the first to fourth side surfaces 5A to 5D. The buffer region 7 includes a pentavalent element and has an impurity concentration that decreases (specifically, decreases gradually) toward the first main surface 3. The buffer region 7 preferably includes any one pentavalent element among phosphorus, nitrogen, arsenic, and antimony. The buffer region 7 preferably includes a pentavalent element other than phosphorus.

Referring to FIG. 3, the buffer region 7 in this embodiment has the impurity concentration that is adjusted by the first impurity (=nitrogen) and has a concentration gradient (concentration distribution) that decreases (specifically, decreases gradually) from the first concentration C1 to a second concentration C2 that is less than the first concentration C1 (C2<C1) from the base region 6 toward the first main surface 3. The second concentration C2 may be not less than 1×10¹⁴ cm⁻³ and not more than 1×10¹⁶ cm⁻³. The buffer region 7 may have a thickness of not less than 0.1 μm and not more than 5 μm. The thickness of the buffer region 7 is preferably not less than 1 μm and not more than 3 μm. In this embodiment, the buffer region 7 is formed in an SiC epitaxial layer.

The SiC semiconductor device 1A includes an n-type drift region 8 that is formed in a surface layer portion of the first main surface 3. The drift region 8 is formed in a region inside the SiC chip 2 between the first main surface 3 and the buffer region 7. The drift region 8 is formed as a layer that extends along the first main surface 3 and is exposed from the first main surface 3 and the first to fourth side surfaces 5A to 5D. The drift region 8 is adjusted in concentration by at least two types of pentavalent elements.

That is, the drift region 8 includes a region in which at least two types of pentavalent elements are present mixedly in the region between the first main surface 3 and the buffer region 7. Preferably, the drift region 8 includes pentavalent elements other than phosphorus and has an impurity concentration that is adjusted by pentavalent elements other than phosphorus. The drift region 8 especially preferably includes nitrogen as a pentavalent element and a pentavalent element other than nitrogen. The drift region 8 preferably includes at least one among arsenic and antimony as a pentavalent element other than phosphorus and nitrogen.

Referring to FIG. 3, the drift region 8 has an impurity concentration that increases toward the first main surface 3. Specifically, the drift region 8 has a concentration gradient (concentration distribution) that increases (specifically, increases gradually) from the second concentration C2 to a third concentration C3 that is greater than the second concentration C2 (C2<C3) from the buffer region 7 toward the first main surface 3. The third concentration C3 is a peak concentration of the drift region 8.

The third concentration C3 suffices to be positioned in a vicinity (surface layer portion) of the first main surface 3 and does not necessarily have to be matched with the first main surface 3. The third concentration C3 is not more than the first concentration C1 (C2<C3≤C1). The third concentration C3 is preferably not less than 10 times the second concentration C2. The third concentration C3 is preferably less than the first concentration C1 (C3<C1). The third concentration C3 may be not less than 1×10¹⁵ cm⁻³ and not more than 1×10¹⁷ cm⁻³.

The drift region 8 has a basal concentration CA and an added concentration CB. The added concentration CB supplements the basal concentration CA. The impurity concentration of the drift region 8 is constituted of a total value of the basal concentration CA and the added concentration CB. The basal concentration CA is due to the first impurity that is a pentavalent element. The first impurity is a pentavalent element other than phosphorus (in this embodiment, nitrogen). The added concentration CB is due to a second impurity that is a pentavalent element other than the first impurity. The second impurity is a pentavalent element other than phosphorus and nitrogen. In this embodiment, the second impurity is at least one among arsenic and antimony.

The drift region 8 has the basal concentration CA (first impurity) and the added concentration CB (second impurity) in a region at the first main surface 3 side and a region at the second main surface 4 side (buffer region 7 side) with respect to an intermediate portion MID between the first main surface 3 and the buffer region 7. In this embodiment, the drift region 8 has the basal concentration CA (first impurity) and the added concentration CB (second impurity) across its entirety in the thickness direction.

The basal concentration CA has a concentration distribution that is substantially constant in the thickness direction. In this embodiment, the basal concentration CA is substantially equal to the second concentration C2 that is a concentration lower limit value of the buffer region 7 (CA≈C2). As a matter of course, the basal concentration CA may have a concentration gradient (concentration distribution) that increases from the buffer region 7 toward the first main surface 3 instead. The added concentration CB has a concentration distribution that increases (specifically, increases gradually) toward the first main surface 3. The added concentration CB exceeds the basal concentration CA (CA<CB). The added concentration CB is preferably not less than 10 times the basal concentration CA. The added concentration CB is preferably less than the first concentration C1 (CA<CB<C1).

The drift region 8 preferably has a thickness that exceeds the thickness of the buffer region 7. The drift region 8 may have a thickness of not less than 1 μm and not more than 25 μm. The drift region 8 may have a thickness belonging to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm. The drift region 8 especially preferably has a thickness of not less than 1 μm and not more than 10 μm. In this embodiment, the drift region 8 is formed in an SiC epitaxial layer.

The SiC semiconductor device 1A includes a functional device 9 that is formed using the drift region 8 at the first main surface 3 side. In FIG. 1 and FIG. 2, the functional device 9 is illustrated in a simplified manner by alternate long and two short dashed lines. The functional device 9 has at least a portion of the drift region 8 as a mobile region (=current path) for carriers. The functional device 9 is formed in an inner portion of the first main surface 3 at intervals from peripheral edges (first to fourth side surfaces 5A to 5D) of the SiC chip 2.

The functional device 9 may include at least one among a semiconductor switching device, a semiconductor rectifying device, and a semiconductor passive device. The semiconductor switching device may include at least one among a MISFET (metal insulator semiconductor field effect transistor), a BJT (bipolar junction transistor), an IGBT (insulated gate bipolar junction transistor), and a JFET (junction field effect transistor). The semiconductor rectifying device may include at least one among a pn-junction diode, a pin junction diode, a Zener diode, an SBD (Schottky barrier diode), and an FRD (fast recovery diode). The semiconductor passive device may include at least one among a resistor and a capacitor.

The functional device 9 may include a circuit network (for example, an integrated circuit such as an LSI) in which at least two among a semiconductor switching device, a semiconductor rectifying device, and a semiconductor passive device are combined. The functional device 9 typically includes at least one among an SiC-MISFET and an SiC-SBD.

As described above, the SiC semiconductor device 1A includes the SiC chip 2, and the drift region 8. The SiC chip 2 has the first main surface 3. The drift region 8 is formed in the surface layer portion of the first main surface 3 and has the impurity concentration that is adjusted by at least two types of pentavalent elements. The at least two types of pentavalent elements are present mixedly in a predetermined thickness range of the surface layer portion of the first main surface 3. With this arrangement, the impurity concentration due to one of the pentavalent elements can be supplemented by the impurity concentration due to the other pentavalent element. The drift region 8 can thereby be made to have the impurity concentration that is reduced in variation with respect to a target concentration. The SiC semiconductor device 1A that can be improved in electrical characteristics can thus be provided.

The drift region 8 preferably has the impurity concentration that is adjusted such as to increase toward the first main surface 3. With this structure, the drift region 8 having the concentration gradient (concentration distribution) that increases toward the first main surface 3 can be formed appropriately by the at least two types of pentavalent elements.

The drift region 8 preferably has the impurity concentration that is adjusted by pentavalent elements other than phosphorus. The drift region 8 preferably includes nitrogen as a pentavalent element and a pentavalent element other than nitrogen. The drift region 8 preferably has the basal concentration CA due to the first impurity that is a pentavalent element and the added concentration CB due to the second impurity that is a pentavalent element other than the first impurity.

The first impurity is preferably a pentavalent element other than phosphorus. The first impurity is preferably nitrogen. The second impurity is preferably a pentavalent element other than phosphorus. The second impurity is preferably at least one among arsenic and antimony. The basal concentration CA preferably has a concentration distribution that is substantially constant in the thickness direction. The added concentration CB preferably has a concentration distribution that increases toward the first main surface 3.

The drift region 8 may have a thickness of not less than 1 μm and not more than 25 μm. With this structure, the impurity concentration of the drift region 8 can be adjusted appropriately by the at least two types of pentavalent elements. The thickness of the drift region 8 is preferably not less than 1 μm and not more than 10 μm.

The SiC chip 2 is preferably constituted of an SiC monocrystal that is a hexagonal crystal. The first main surface 3 is preferably arranged along a c-plane of the SiC monocrystal. The first main surface 3 preferably has the off angle 9 of not more than 10° with respect to the c-plane. The off angle θ preferably has the off direction D oriented along the a-axis direction of the SiC monocrystal. The drift region 8 is preferably formed in the SiC epitaxial layer. The SiC semiconductor device 1A preferably includes the functional device 9 that is formed using at least a portion of the drift region 8 at the first main surface 3. With this structure, the electrical characteristics of the functional device 9 can be improved.

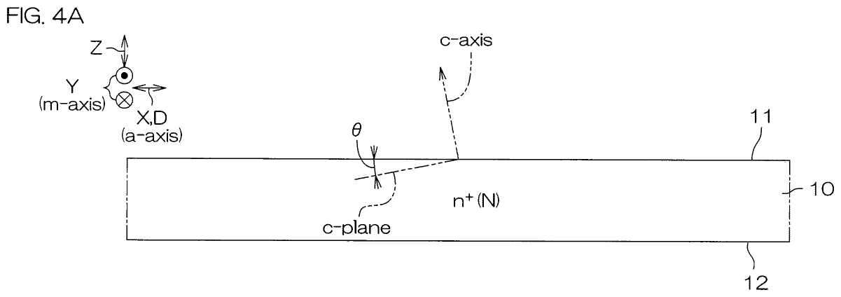

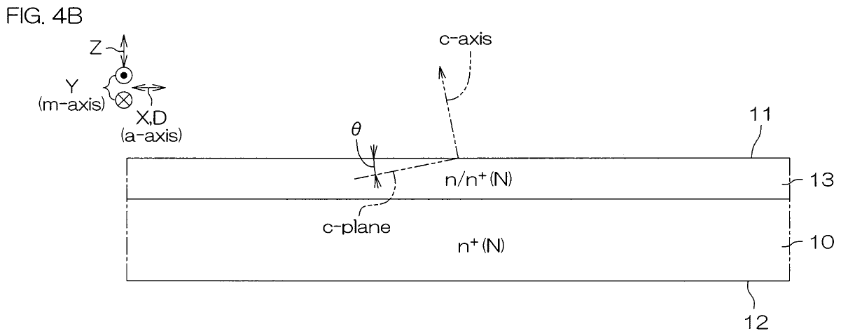

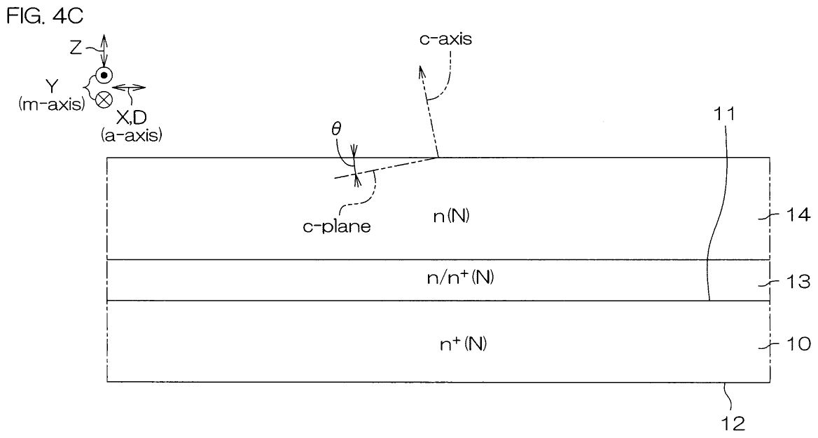

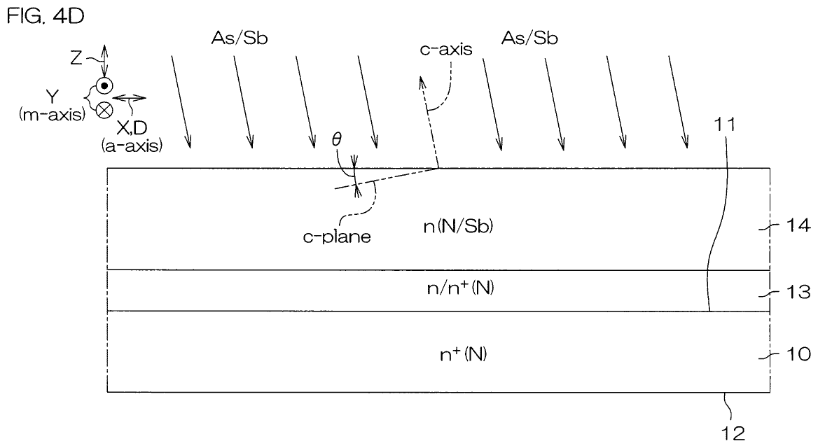

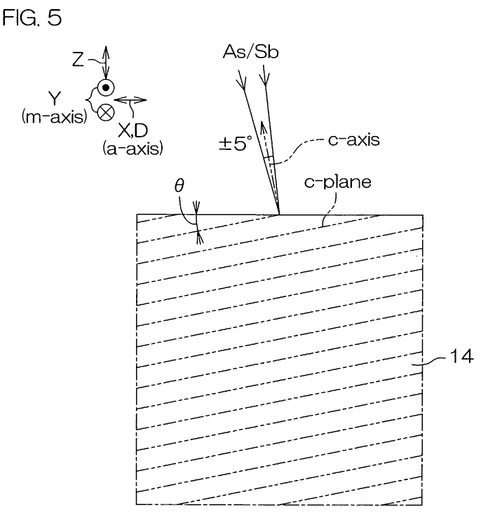

FIG. 4A to FIG. 4D are sectional views of a method for manufacturing the SiC semiconductor device 1A shown in FIG. 1. FIG. 5 is a sectional view for specifically describing the step of FIG. 4D.

Referring to FIG. 4A, an n-type SiC wafer 10 is prepared. The SiC wafer 10 is a monocrystal plate of disk shape. The SiC wafer 10 has an impurity concentration that is adjusted by the first impurity. The first impurity is preferably a pentavalent element other than phosphorus. The first impurity is preferably constituted of one type of pentavalent element. The first impurity is preferably one among nitrogen, arsenic, and antimony. In this embodiment, the first impurity is nitrogen. The SiC wafer 10 has the first concentration C1 that is substantially constant in the thickness direction. The SiC wafer 10 becomes a base of the base region 6.

The SiC wafer 10 has a first wafer main surface 11 at one side and a second wafer main surface 12 at another side. The first wafer main surface 11 and the second wafer main surface 12 are arranged along c-planes of the SiC monocrystal. The c-planes include silicon planes ((0001) planes) and carbon planes ((000-1) planes) of the SiC monocrystal. Preferably, the first wafer main surface 11 is arranged along a silicon plane and the second wafer main surface 12 is arranged along a carbon plane. The first wafer main surface 11 and the second wafer main surface 12 are respectively arranged along c-planes of the SiC monocrystal. Preferably, the first wafer main surface 11 is formed by a silicon plane of the SiC monocrystal and the second wafer main surface 12 is formed by a carbon plane of the SiC monocrystal.

The first wafer main surface 11 and the second wafer main surface 12 have the off angle θ inclined at the predetermined angle in the off direction D with respect to the c-planes. The off direction D is preferably the a-axis direction ([11-20] direction) of the SiC monocrystal. The off angle θ may exceed 0° and be not more than 100. The off angle θ is preferably not more than 5°. The off angle θ is especially preferably not less than 2° and not more than 4.5°. The SiC wafer 10 may have a thickness of not less than 50 μm and not more than 500 μm. The thickness of the SiC wafer 10 is adjusted by grinding of the second wafer main surface 12.

Referring to FIG. 4B, an n-type first SiC epitaxial layer 13 is formed on the first wafer main surface 11 by an epitaxial growth method. The first SiC epitaxial layer 13 is formed in a mode of inheriting the off direction D and the off angle θ from the SiC wafer 10. The first SiC epitaxial layer 13 is formed by epitaxially growing SiC on the first wafer main surface 11 while introducing a pentavalent element (in this embodiment, the first impurity). An impurity concentration of the first SiC epitaxial layer 13 is adjusted such as to decrease (specifically, decrease gradually) from the first concentration C1 to the second concentration C2 with the SiC wafer 10 as a starting point. The first SiC epitaxial layer 13 becomes a base of the buffer region 7.

Referring to FIG. 4C, an n-type second SiC epitaxial layer 14 is formed on the first SiC epitaxial layer 13 by an epitaxial growth method. The second SiC epitaxial layer 14 is formed in a mode of inheriting the off direction D and the off angle 9 from the first SiC epitaxial layer 13. The second SiC epitaxial layer 14 is formed on the first SiC epitaxial layer 13 while introducing a pentavalent element (in this embodiment, the first impurity) by epitaxially growing SiC. An impurity concentration of the second SiC epitaxial layer 14 is adjusted such as to be substantially constant in a crystal growth direction.

In this embodiment, the impurity concentration of the second SiC epitaxial layer 14 is adjusted such as to maintain the substantially constant second concentration C2 in the crystal growth direction from the first SiC epitaxial layer 13. As a matter of course, the impurity concentration of the second SiC epitaxial layer 14 may instead be adjusted such as to increase (specifically, increase gradually) in the crystal growth direction from the first SiC epitaxial layer 13. The second SiC epitaxial layer 14 becomes a base of the drift region 8. That is, the second SiC epitaxial layer 14 is formed to be of a lower concentration than the target concentration of the drift region 8.

Referring to FIG. 4D, a pentavalent element is implanted into the second SiC epitaxial layer 14 by an ion implantation method to form the n-type drift region 8 that has the target concentration. In this step, the pentavalent element is implanted into an entirety of the second SiC epitaxial layer 14 such that the impurity concentration increases (specifically, increases gradually) in the crystal growth direction. The n-type drift region 8 having the concentration gradient (target concentration) that increases from the second concentration C2 to the third concentration C3 in the crystal growth direction is thereby formed.

Referring to FIG. 5, in this embodiment, the ion implantation method is a channeling implantation method. With the channeling implantation method, the pentavalent element is implanted into the second SiC epitaxial layer 14 along a direction in which the atomic arrangement of the SiC monocrystal is sparse (=crystal axis direction). The crystal axis of the SiC monocrystal is, specifically, a c-axis (<0001>axis) of the SiC monocrystal. With this method, a probability that the pentavalent element would collide against a constituent atom of the SiC monocrystal is reduced and therefore, the pentavalent element is implanted to a deep region of the second SiC epitaxial layer 14. In this step, the pentavalent element is implanted in a region at a main surface (crystal growth surface) side and a region at the SiC wafer 10 side of the second SiC epitaxial layer 14 with respect to an intermediate portion of the second SiC epitaxial layer 14.

In this step, the second impurity that is constituted of a pentavalent element that differs from the first impurity (=nitrogen) included in the second SiC epitaxial layer 14 is implanted. In this embodiment, the second impurity is at least one among arsenic and antimony. The drift region 8 having the basal concentration CA (=second concentration C2) due to the first impurity and the added concentration CB due to the second impurity is thereby formed. The basal concentration CA has the concentration distribution that is substantially constant in the thickness direction. The added concentration CB has the concentration distribution that increases toward the first main surface 3.

An implantation depth of the second impurity with respect to the second SiC epitaxial layer 14 is adjusted precisely by adjusting an implantation energy of the second impurity, an implantation temperature of the second impurity, an implantation angle of the second impurity, etc. The implantation energy of the second impurity may be adjusted in a range of not less than 10 keV and not more than 1000 keV (preferably, not more than 100 keV). The implantation temperature of the second impurity may be adjusted in a range of not less than 300° C. and not more than 1000° C.

The implantation angle of the second impurity is set in a range of ±5° with the crystal axis (=c-axis) of the SiC monocrystal as a basis (=0°). The implantation angle of the second impurity is preferably set in a range of ±2°. In this embodiment, the second SiC epitaxial layer 14 (SiC wafer 10) has the off angle θ that is inclined in the predetermined off direction D. The implantation angle of the second impurity with respect to the second SiC epitaxial layer 14 or an inclination angle of the second SiC epitaxial layer 14 with respect to an implantation direction of the second impurity is therefore adjusted in accordance with the off direction D and the off angle θ.

As a matter of course, the second impurity may be phosphorus or nitrogen as the pentavalent element. However, phosphorus or nitrogen has a property of being difficult to implant into a deep region of the second SiC epitaxial layer 14 by the channeling implantation method. The second impurity is therefore preferably at least one among arsenic and antimony.

After the implantation of the second impurity, the second impurity is electrically activated and lattice defects, etc., that formed in the second SiC epitaxial layer 14 are repaired at the same time by an annealing method. An annealing temperature of the second SiC epitaxial layer 14 may be not less than 500° C. and not more than 2000° C. The drift region 8 is thereby formed. Thereafter, the functional device 9 that uses a portion of the drift region 8 is formed at the main surface (crystal growth surface) side of the second SiC epitaxial layer 14. The SiC semiconductor device 1A is manufactured through steps including the above.

It may be considered to form the second SiC epitaxial layer 14 having the target concentration of the drift region 8 from the beginning by an epitaxial growth method. However, with this method, it is difficult to accurately control an introduction amount of the pentavalent element and the drift region 8 that has a comparatively large concentration variation with respect to the target concentration is formed. Such a problem becomes more significant as the second SiC epitaxial layer 14 becomes thicker. Also, such a problem becomes more significant as the impurity concentration of the second SiC epitaxial layer 14 increases.

On the other hand, with the method for manufacturing the SiC semiconductor device 1A, a first step of preparing the n-type second SiC epitaxial layer 14 and a second step of forming the n-type drift region 8 are performed. In the first step, the n-type second SiC epitaxial layer 14 of low concentration is prepared. Specifically, the impurity concentration of the second SiC epitaxial layer 14 is less than the target concentration of the drift region 8. In the second step, the pentavalent element (n-type impurity) is implanted into the second SiC epitaxial layer 14 by the ion implantation method to form the n-type drift region 8 having the target concentration.

With this manufacturing method, the impurity concentration of the second SiC epitaxial layer 14 is supplemented by the impurity concentration that is increased due to the ion implantation method. In comparison to an epitaxial growth method that accompanies the introduction of an impurity, the introduction amount of the impurity can be adjusted appropriately by the ion implantation method. The concentration variation of the drift region 8 with respect to the target concentration can thereby be reduced. The SiC semiconductor device 1A that can be improved in electrical characteristics can thus be manufactured and provided.

In the method for manufacturing the SiC semiconductor device 1A, the second SiC epitaxial layer 14 having the impurity concentration that is adjusted by the first impurity may be prepared. In this case, the drift region 8 may be formed by implanting the second impurity that differs from the first impurity into the second SiC epitaxial layer 14. The first impurity is preferably a pentavalent element other than phosphorus. The first impurity is preferably nitrogen. The second impurity is preferably a pentavalent element other than phosphorus. The second impurity is preferably at least one among arsenic and antimony.

The ion implantation method is preferably the channeling implantation method of implanting the second impurity along the crystal axis of the second SiC epitaxial layer 14. The second impurity is preferably implanted into the second SiC epitaxial layer 14 at the implantation angle of not more than ±5° on the basis of the crystal axis of the SiC monocrystal. The crystal axis of the SiC monocrystal is preferably the c-axis. The second SiC epitaxial layer 14 preferably has the off angle θ of not more than 10° with respect to the c-plane of the SiC monocrystal. The off angle θ preferably has the off direction D that is oriented along the a-axis direction of the SiC monocrystal.

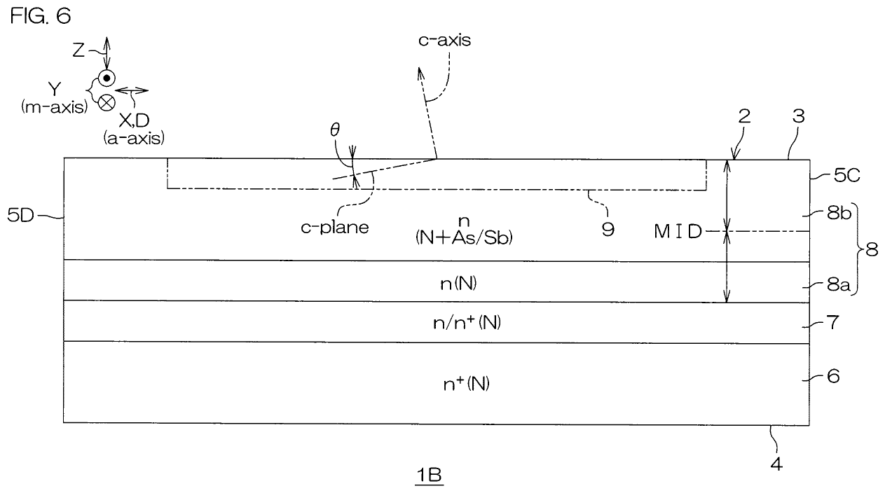

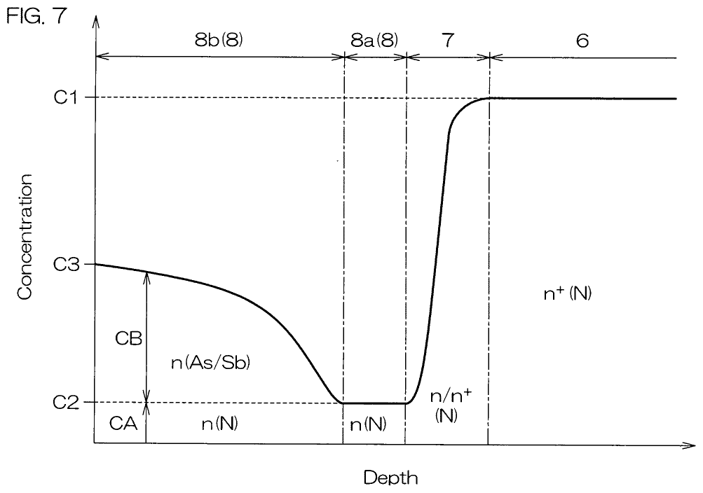

FIG. 6 corresponds to FIG. 2 and is a sectional view of an SiC semiconductor device 1B according to a second preferred embodiment. FIG. 7 is a graph of impurity concentration inside the SiC chip 2 shown in FIG. 6. In FIG. 7, the ordinate indicates the impurity concentration and the abscissa indicates depth. In the following, structures corresponding to the structures described with the first preferred embodiment shall be provided with the same reference signs and description thereof shall be omitted.

Referring to FIG. 6 and FIG. 7, the SiC semiconductor device 1B, as with the SiC semiconductor device 1A, includes the SiC chip 2, the n-type base region 6, the n-type buffer region 7, the n-type drift region 8, and the functional device 9. In this embodiment, the drift region 8 includes a first region 8a and a second region 8b that are formed in that order from a bottom portion toward the first main surface 3.

The first region 8a is a region having an impurity concentration adjusted by one type of pentavalent element and is formed separated from the first main surface 3 in a surface layer portion of the first main surface 3. Specifically, the first region 8a is formed on the buffer region 7 as a layer that extends along the first main surface 3 and is exposed from the first to fourth side surfaces 5A to 5D. The first region 8a is formed in a region at the second main surface 4 side (buffer region 7 side) with respect to an intermediate portion MID. The first region 8a is preferably formed at an interval to the second main surface 4 side from the intermediate portion MID.

The first region 8a includes a first impurity and has a basal concentration CA due to the first impurity. The first impurity is the same as in the case of the first preferred embodiment. That is, the first impurity may be any one among phosphorus, nitrogen, arsenic, and antimony. The first impurity is preferably a pentavalent element other than phosphorus. In this embodiment, the first impurity is nitrogen. The basal concentration CA is substantially equal to the concentration lower limit value (=second concentration C2) of the buffer region 7 (CA≈C2). The first region 8a has a concentration distribution that is substantially constant in the thickness direction. As a matter of course, the first region 8a may have a concentration gradient (concentration distribution) that increases toward the first main surface 3 with the buffer region 7 (second concentration C2) as a starting point instead.

The second region 8b is a region having an impurity concentration that is adjusted by at least two types of pentavalent elements. The second region 8b is formed as a layer extending along the first main surface 3 in a region between the first main surface 3 and the first region 8a and is exposed from the first main surface 3 and the first to fourth side surfaces 5A to 5D. The second region 8b is formed in a region at the first main surface 3 side with respect to the intermediate portion MID. The second region 8b preferably traverses the intermediate portion MID and is formed in a region at the second main surface 4 side as well.

The second region 8b has a concentration gradient (concentration distribution) that increases (specifically, increases gradually) from the basal concentration CA (≈second concentration C2) to the third concentration C3 of the first region 8a. In this embodiment, the second region 8b has the basal concentration CA due to the first impurity and an added concentration CB due to a second impurity constituted of a pentavalent element other than the first impurity. The second impurity is the same as in the case of the first preferred embodiment. That is, the second impurity preferably includes at least one among arsenic and antimony.

As in the case of the first preferred embodiment, the basal concentration CA of the second region 8b has a substantially constant concentration distribution in the thickness direction. As a matter of course, the basal concentration CA of the second region 8b may have a concentration gradient (concentration distribution) that increases toward the first main surface 3. As in the case of the first preferred embodiment, the added concentration CB of the second region 8b has a concentration gradient (concentration distribution) that increases toward the first main surface 3. The second region 8b has a resistance value less than a resistance value of the first region 8a. That is, the first region 8a is a high resistance region and the second region 8b is a low resistance region.

Even with the SiC semiconductor device 1B described above, the same effects as the effects described for the SiC semiconductor device 1A are exhibited.

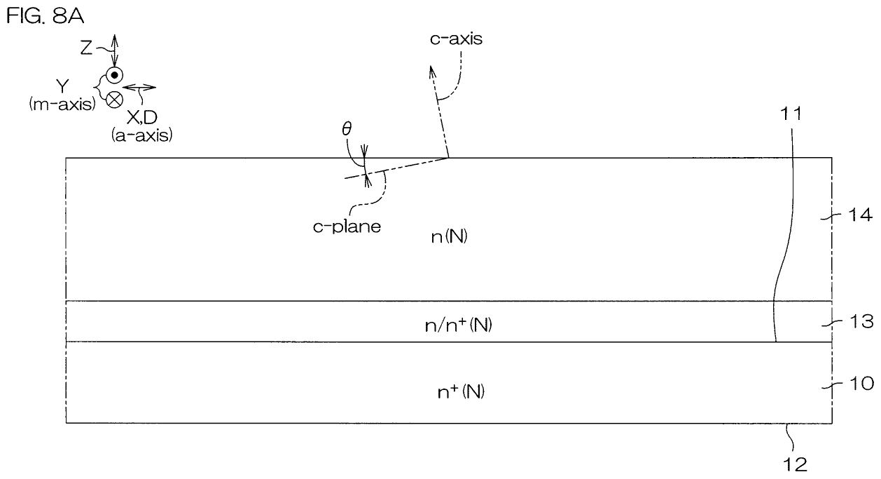

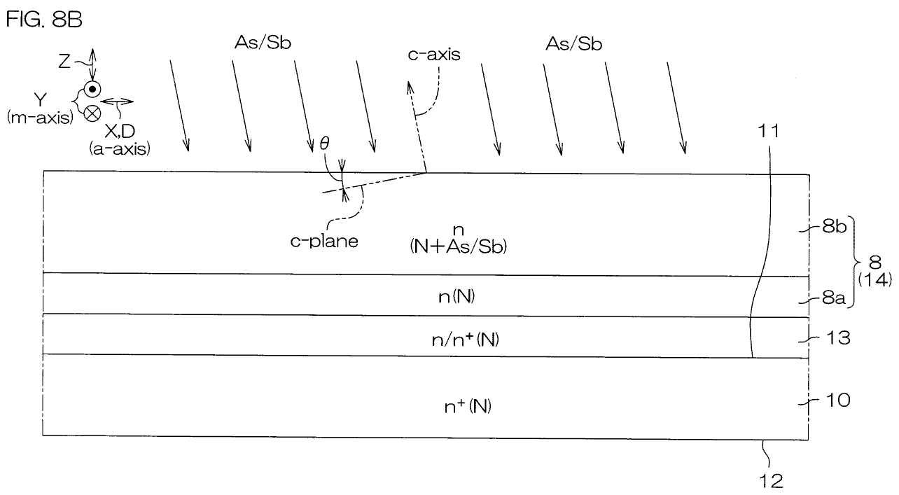

FIG. 8A and FIG. 8B are sectional views of a method for manufacturing the SiC semiconductor device 1B shown in FIG. 6. Referring to FIG. 8A, the first SiC epitaxial layer 13 and the second SiC epitaxial layer 14 are formed on the SiC wafer 10 through the same steps as in FIG. 4A to FIG. 4C.

Referring to FIG. 8B, as in the step of FIG. 4D, a pentavalent element (n-type impurity) is implanted by an ion implantation method (in this embodiment, a channeling implantation method) to a thickness intermediate portion of the second SiC epitaxial layer 14 and the n-type drift region 8 having the target concentration is formed. In this embodiment, the drift region 8 includes the first region 8a that is constituted of a portion of the second SiC epitaxial layer 14 and the second region 8b in which the pentavalent element is implanted further into the second SiC epitaxial layer 14. The impurity concentration of the second region 8b is adjusted such as to increase in the crystal growth direction of the second SiC epitaxial layer 14.

In this step, the second impurity (=at least one among arsenic and antimony) that is constituted of a pentavalent element differing from the first impurity (=nitrogen) included in the second SiC epitaxial layer 14 is implanted to the thickness intermediate portion of the second SiC epitaxial layer 14. The first region 8a having the basal concentration CA (=second concentration C2) due to the first impurity is thereby formed. The second region 8b having the basal concentration CA due to the first impurity and the added concentration CB due to the second impurity is also formed.

Even with the method for manufacturing the SiC semiconductor device 1B described above, the same effects as those described for the method for manufacturing the SiC semiconductor device 1A are exhibited.

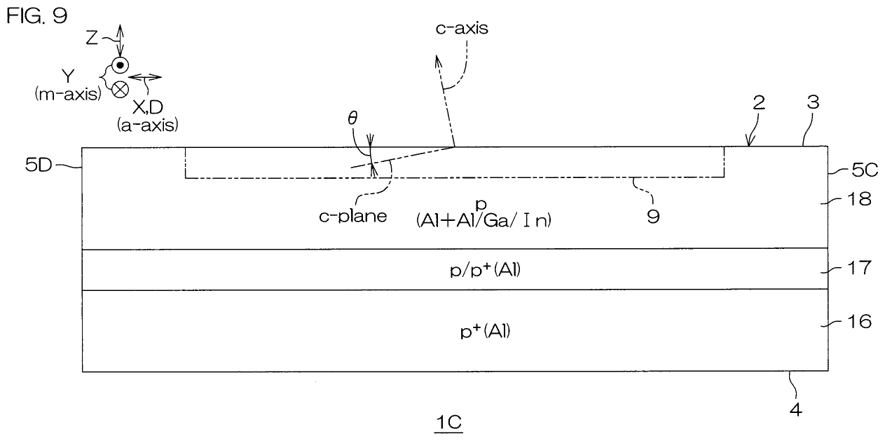

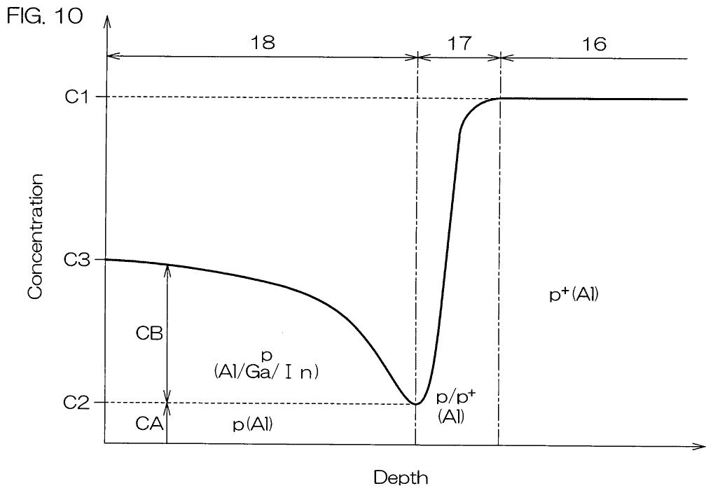

FIG. 9 corresponds to FIG. 2 and is a sectional view of an SiC semiconductor device 1C according to a third preferred embodiment. FIG. 10 is a graph of impurity concentration inside the SiC chip 2 shown in FIG. 9. In FIG. 10, the ordinate indicates the impurity concentration and the abscissa indicates depth. In the following, structures corresponding to the structures described with the first and second preferred embodiments shall be provided with the same reference signs and description thereof shall be omitted.

Referring to FIG. 9 and FIG. 10, the SiC semiconductor device 1C has a structure in which the “n-type regions” in the SiC semiconductor device 1A are replaced by “p-type regions.” Specifically, the SiC semiconductor device 1C includes a p-type base region 16, a p-type buffer region 17, and a p-type drift region 18 in place of the n-type base region 6, the n-type buffer region 7, and the n-type drift region 8.

The p-type base region 16 has an impurity concentration that is adjusted by a first impurity (=p-type impurity) constituted of a trivalent element. The first impurity is preferably constituted of one type of trivalent element. The first impurity may be any one among boron (B), aluminum (Al), gallium (G), and indium (I). The first impurity is preferably a trivalent element other than boron. In this embodiment, the first impurity is aluminum.

The base region 16 has a first concentration C1 that is substantially constant in a thickness direction. The first concentration C1 may be not less than 1×10¹⁸ cm⁻³ and not more than 1×10²¹ cm⁻³. The base region 16 may have a thickness not less than 5 μm and not more than 300 μm. The thickness of the base region 16 is preferably not less than 50 μm and not more than 250 μm. In this embodiment, the base region 16 is formed in an SiC substrate.

The p-type buffer region 17 includes a trivalent element and has an impurity concentration that is adjusted such as to decrease (specifically, decrease gradually) toward the first main surface 3. The buffer region 17 preferably includes any one among boron, aluminum, gallium, and indium. The buffer region 17 preferably includes a trivalent element other than boron. In this embodiment, the buffer region 17 is adjusted in concentration by the first impurity (=aluminum).

The buffer region 17 has a concentration gradient (concentration distribution) that decreases (specifically, decreases gradually) from the first concentration C1 to a second concentration C2 that is less than the first concentration C1 (C2<C1) from the base region 16 toward the first main surface 3. The second concentration C2 may be not less than 1×10¹⁴ cm⁻³ and not more than 1×10¹⁶ cm⁻³. The buffer region 17 may have a thickness of not less than 0.1 μm and not more than 5 μm. The thickness of the buffer region 17 is preferably not less than 1 μm and not more than 3 μm. In this embodiment, the buffer region 17 is formed in an SiC epitaxial layer.

The p-type drift region 18 includes a trivalent element other than boron and has an impurity concentration that is adjusted by a trivalent element other than boron. The drift region 18 preferably includes at least one among aluminum, gallium, and indium. The drift region 18 has the impurity concentration that is adjusted such as to increase toward the first main surface 3. Specifically, the drift region 18 has a concentration gradient (concentration distribution) that increases (specifically, increases gradually) from the second concentration C2 to a third concentration C3 that is greater than the second concentration C2 (C2<C3) from the buffer region 17 toward the first main surface 3.

The third concentration C3 is a peak concentration of the drift region 18. The third concentration C3 suffices to be positioned in a vicinity (surface layer portion) of the first main surface 3 and does not necessarily have to be matched with the first main surface 3. The third concentration C3 is not more than the first concentration C1 (C3<C1). The third concentration C3 is preferably not less than 10 times the second concentration C2. The third concentration C3 is preferably less than the first concentration C1 (C2<C3<C1). The third concentration C3 may be not less than 1×10¹⁵ cm⁻³ and not more than 1×10¹⁷ cm⁻³.

The drift region 18 has a basal concentration CA and an added concentration CB. The added concentration CB supplements the basal concentration CA. The impurity concentration (third concentration C3) of the drift region 18 is constituted of a total value of the basal concentration CA and the added concentration CB. The basal concentration CA is due to the first impurity that is a trivalent element. The added concentration CB is due to a second impurity that is the same type of trivalent element as the first impurity or is a trivalent element of a different type from the first impurity. The second impurity may be at least one among aluminum, gallium, and indium. In this embodiment, the second impurity is aluminum.

The drift region 18 has the basal concentration CA (first impurity) and the added concentration CB (second impurity) in a region at the first main surface 3 side and a region at the second main surface 4 side (buffer region 17 side) with respect to an intermediate portion MID. In this embodiment, the drift region 18 has the basal concentration CA (first impurity) and the added concentration CB (second impurity) across its entirety in the thickness direction.

The basal concentration CA has a concentration distribution that is substantially constant in the thickness direction. In this embodiment, the basal concentration CA is substantially equal to the second concentration C2 that is a concentration lower limit value of the buffer region 17 (CA≈C2). As a matter of course, the basal concentration CA may have a concentration gradient (concentration distribution) that increases (specifically, increases gradually) from the buffer region 17 toward the first main surface 3 instead. The added concentration CB has a concentration distribution that increases toward the first main surface 3. The added concentration CB exceeds the basal concentration CA (CA<CB). The added concentration CB is preferably not less than 10 times the basal concentration CA. The added concentration CB is preferably less than the first concentration C1 (CA<CB<C1).

The drift region 18 preferably has a thickness that exceeds the thickness of the buffer region 17. The drift region 18 may have a thickness of not less than 1 μm and not more than 25 μm. The drift region 18 may have a thickness belonging to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm. The drift region 18 especially preferably has a thickness of not less than 1 μm and not more than 10 μm. In this embodiment, the drift region 18 is formed in an SiC epitaxial layer.

Even with the SiC semiconductor device 1C described above, the same effects as the effects described for the SiC semiconductor device 1A are exhibited. The SiC semiconductor device 1C is manufactured by replacing the pentavalent elements in the method for manufacturing the SiC semiconductor device 1A (FIG. 4A to FIG. 4D) by predetermined trivalent elements. Therefore, even with the method for manufacturing the SiC semiconductor device 1C, the same effects as those described for the method for manufacturing the SiC semiconductor device 1A are exhibited.

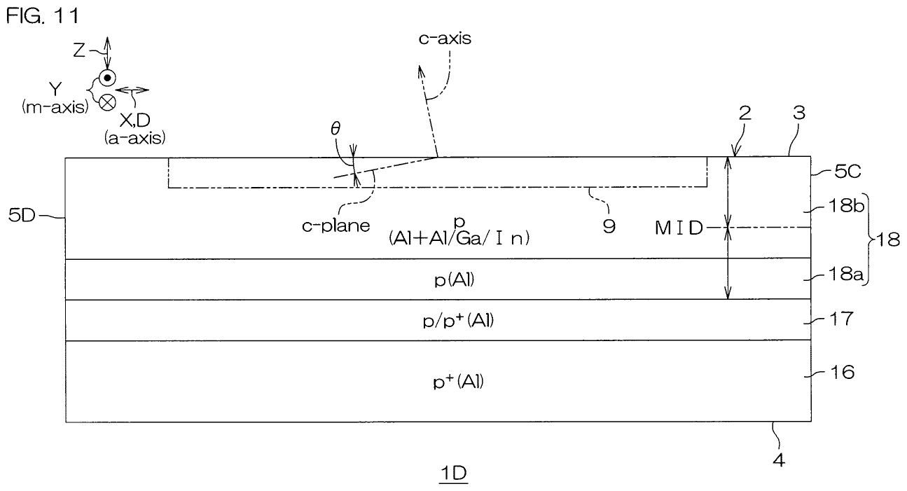

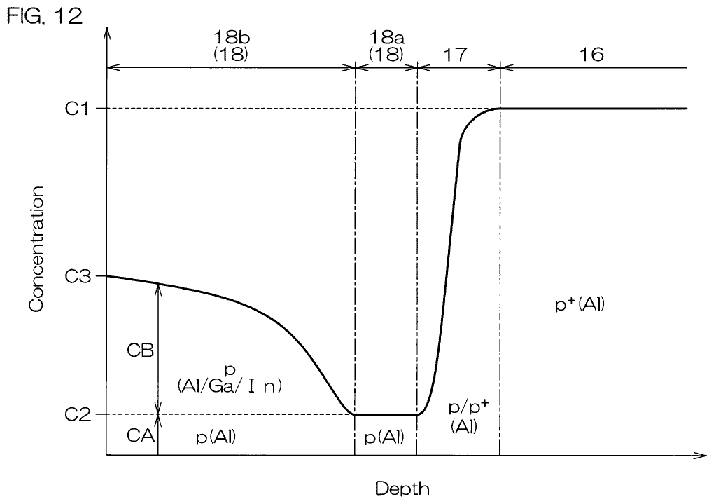

FIG. 11 corresponds to FIG. 9 and is a sectional view of an SiC semiconductor device 1D according to a fourth preferred embodiment. FIG. 12 is a graph of impurity concentration inside the SiC chip 2 shown in FIG. 11. In FIG. 12, the ordinate indicates the impurity concentration and the abscissa indicates depth. In the following, structures corresponding to the structures described with the first to third preferred embodiments shall be provided with the same reference signs and description thereof shall be omitted.

Referring to FIG. 11 and FIG. 12, the SiC semiconductor device 1D, as in the case of the SiC semiconductor device 1C, includes the SiC chip 2, the p-type base region 16, the p-type buffer region 17, the p-type drift region 18, and the functional device 9. As with the third preferred embodiment, the drift region 18 has an impurity concentration that is adjusted by a trivalent element other than boron. In this embodiment, the drift region 18 includes a first region 18a and a second region 18b that are formed in that order from a bottom portion toward the first main surface 3.

The first region 18a is a region having an impurity concentration adjusted by one type of trivalent element and is formed separated from the first main surface 3 in a surface layer portion of the first main surface 3. Specifically, the first region 18a is formed on the buffer region 17 as a layer that extends along the first main surface 3 and is exposed from the first to fourth side surfaces 5A to 5D. The first region 18a is formed in a region at the second main surface 4 side (buffer region 17 side) with respect to the intermediate portion MID. The first region 18a is preferably formed at an interval to the second main surface 4 side from the intermediate portion MID.

In this embodiment, the first region 18a includes a first impurity that is a trivalent element and has a basal concentration CA due to the first impurity. The first impurity may be any one among aluminum, gallium, and indium. In this embodiment, the first impurity is aluminum. The basal concentration CA is substantially equal to the second concentration C2 that is the concentration lower limit value of the buffer region 17 (CA≈C2). The first region 18a has a concentration distribution that is substantially constant in the thickness direction. As a matter of course, the first region 18a may have a concentration gradient (concentration distribution) that increases toward the first main surface 3 with the buffer region 17 (second concentration C2) as a starting point instead.

The second region 18b is formed in a region between the first main surface 3 and the first region 18a. The second region 18b is formed as a layer extending along the first main surface 3 and is exposed from the first main surface 3 and the first to fourth side surfaces 5A to 5D. The second region 18b is formed in a region at the first main surface 3 side with respect to the intermediate portion MID. The second region 18b preferably traverses the intermediate portion MID and is formed in a region at the second main surface 4 side as well.

The second region 18b is a region having an impurity concentration adjusted by the first impurity and a second impurity that is the same type of trivalent element as the first impurity or is a trivalent element of a different type from the first impurity. The second impurity may be at least one among aluminum, gallium, and indium. In this embodiment, the second impurity is aluminum. The second region 18b has a concentration gradient (concentration distribution) that increases (specifically, increases gradually) from the basal concentration CA (=second concentration C2) to a third concentration C3 of the first region 18a. In this embodiment, the second region 18b has the basal concentration CA due to the first impurity and an added concentration CB due to the second impurity.

As in the case of the third preferred embodiment, the basal concentration CA of the second region 18b has a substantially constant concentration distribution in the thickness direction. As a matter of course, the basal concentration CA of the second region 18b may have a concentration gradient (concentration distribution) that increases toward the first main surface 3. As in the case of the third preferred embodiment, the added concentration CB has a concentration gradient (concentration distribution) that increases toward the first main surface 3. The second region 18b has a resistance value less than a resistance value of the first region 18a. That is, the first region 18a is a high resistance region and the second region 18b is a low resistance region.

Even with the SiC semiconductor device 1D described above, the same effects as the effects described for the SiC semiconductor device 1A are exhibited. The SiC semiconductor device 1D is manufactured by replacing the pentavalent elements in the method for manufacturing the SiC semiconductor device 1B according to the second preferred embodiment (FIG. 8A and FIG. 8B) by predetermined trivalent elements. Therefore, even with the method for manufacturing the SiC semiconductor device 1D, the same effects as those described for the method for manufacturing the SiC semiconductor device 1A are exhibited.

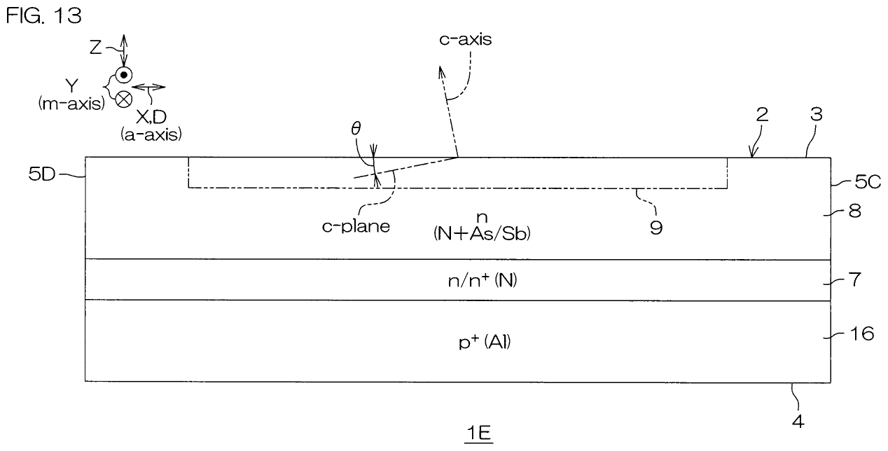

FIG. 13 corresponds to FIG. 2 and is a sectional view of an SiC semiconductor device 1E according to a fifth preferred embodiment. In the following, structures corresponding to the structures described with the first to fourth preferred embodiments shall be provided with the same reference signs and description thereof shall be omitted.

Referring to FIG. 13, the SiC semiconductor device 1E has a structure in which the n-type base region 6 according to the first preferred embodiment is changed to the p-type base region 16 according to the third preferred embodiment. In this case, the n-type buffer region 17 may have, at a boundary portion with the p-type base region 6, an offset region that offsets a p-type impurity concentration due to a trivalent element of the base region 6 by an n-type impurity concentration due to a pentavalent element.

Even with the SiC semiconductor device 1E described above, the same effects as the effects described for the SiC semiconductor device 1A are exhibited. The SiC semiconductor device 1E is manufactured by preparing, in the method for manufacturing the SiC semiconductor device 1A (FIG. 4A to FIG. 4D), a p-type SiC wafer 10 having an impurity concentration adjusted by a predetermined trivalent element. Therefore, even with the method for manufacturing the SiC semiconductor device 1E, the same effects as those described for the method for manufacturing the SiC semiconductor device 1A according to the first preferred embodiment are exhibited.

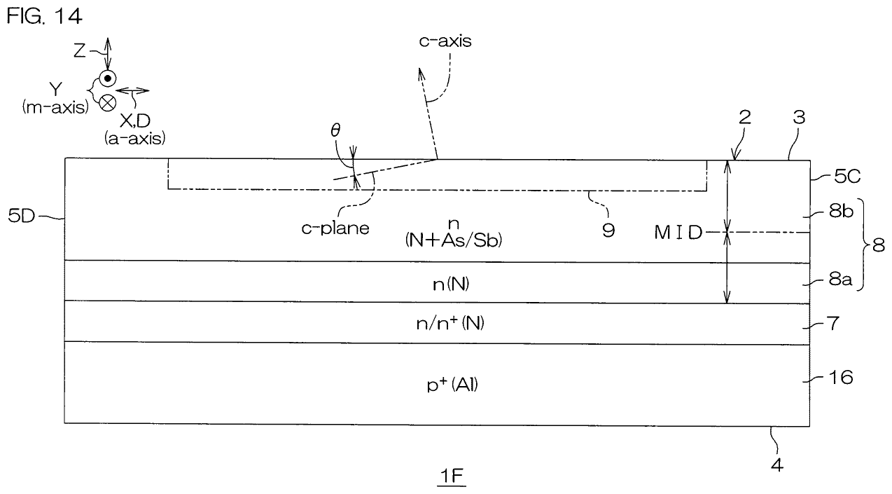

FIG. 14 corresponds to FIG. 6 and is a sectional view of an SiC semiconductor device 1F according to a sixth preferred embodiment. In the following, structures corresponding to the structures described with the first to fifth preferred embodiments shall be provided with the same reference signs and description thereof shall be omitted.

Referring to FIG. 14, the SiC semiconductor device 1F has a structure in which the n-type base region 6 according to the second preferred embodiment is changed to the p-type base region 16 according to the third preferred embodiment. In this case, the n-type buffer region 17 may have, at a boundary portion with the p-type base region 6, an offset region that offsets a p-type impurity concentration due to a trivalent element of the base region 6 by an n-type impurity concentration due to a pentavalent element.

Even with the SiC semiconductor device 1F described above, the same effects as the effects described for the SiC semiconductor device 1A are exhibited. The SiC semiconductor device 1F is manufactured by preparing, in the method for manufacturing the SiC semiconductor device 1A (FIG. 4A to FIG. 4D and FIG. 8A and FIG. 8B), a p-type SiC wafer 10 having an impurity concentration adjusted by a predetermined trivalent element. Therefore, even with the method for manufacturing the SiC semiconductor device 1F, the same effects as those described for the method for manufacturing the SiC semiconductor device 1A are exhibited.

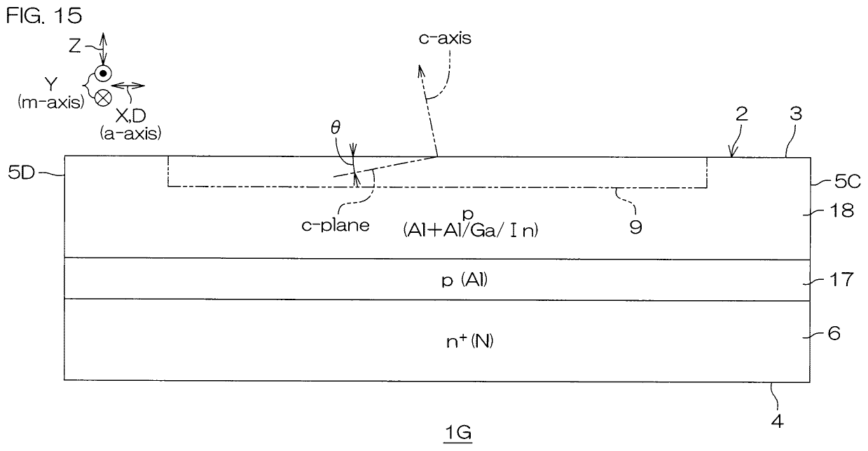

FIG. 15 corresponds to FIG. 2 and is a sectional view of an SiC semiconductor device 1G according to a seventh preferred embodiment. In the following, structures corresponding to the structures described with the first to sixth preferred embodiments shall be provided with the same reference signs and description thereof shall be omitted.

Referring to FIG. 15, the SiC semiconductor device 1G has a structure in which the p-type base region 16 according to the third preferred embodiment is changed to the n-type base region 6 according to the first preferred embodiment. In this case, the p-type buffer region 17 may have, at a boundary portion with the n-type base region 6, an offset region that offsets an n-type impurity concentration due to a pentavalent element of the base region 6 by a p-type impurity concentration due to a trivalent element.

Even with the SiC semiconductor device 1G described above, the same effects as the effects described for the SiC semiconductor device 1A are exhibited. The SiC semiconductor device 1G is manufactured by preparing, in the method for manufacturing the SiC semiconductor device 1C according to the third preferred embodiment, an n-type SiC wafer 10 having an impurity concentration adjusted by a predetermined pentavalent element. Therefore, even with the method for manufacturing the SiC semiconductor device 1G, the same effects as those described for the method for manufacturing the SiC semiconductor device 1A according to the first preferred embodiment are exhibited.

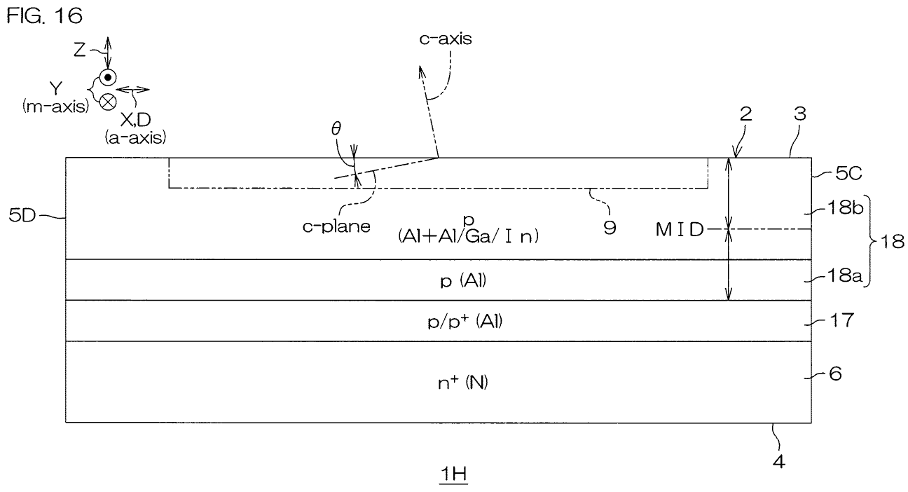

FIG. 16 corresponds to FIG. 6 and is a sectional view of an SiC semiconductor device 1H according to an eighth preferred embodiment. In the following, structures corresponding to the structures described with the first to seventh preferred embodiments shall be provided with the same reference signs and description thereof shall be omitted.

Referring to FIG. 16, the SiC semiconductor device 1H has a structure in which the p-type base region 16 according to the fourth preferred embodiment is changed to the n-type base region 6 according to the first preferred embodiment. In this case, the p-type buffer region 17 may have, at a boundary portion with the n-type base region 6, an offset region that offsets an n-type impurity concentration due to a pentavalent element of the base region 6 by a p-type impurity concentration due to a trivalent element.

Even with the SiC semiconductor device 1H described above, the same effects as the effects described for the SiC semiconductor device 1A are exhibited. The SiC semiconductor device 1H is manufactured by preparing, in the method for manufacturing the SiC semiconductor device 1D according to the fourth preferred embodiment, an n-type SiC wafer 10 having an impurity concentration adjusted by a predetermined pentavalent element. Therefore, even with the method for manufacturing the SiC semiconductor device 1H, the same effects as those described for the method for manufacturing the SiC semiconductor device 1A according to the first preferred embodiment are exhibited.

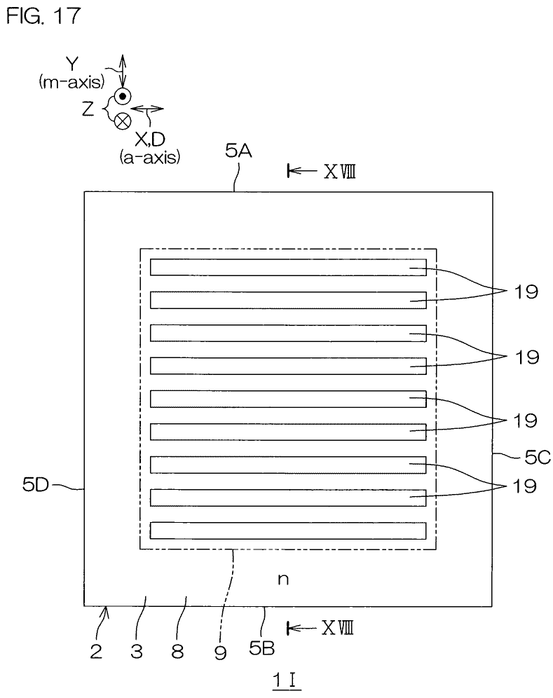

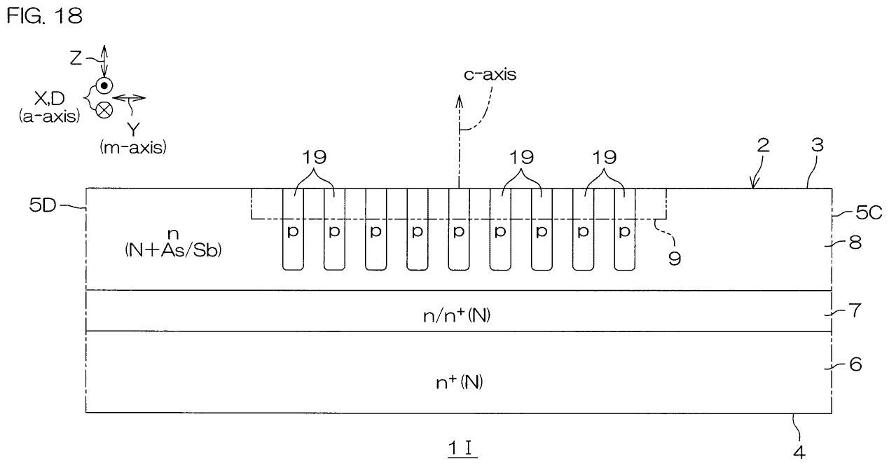

FIG. 17 is a plan view of an SiC semiconductor device 1I according to a ninth preferred embodiment. FIG. 18 is a sectional view taken along line XVIII-XVIII shown in FIG. 17. In the following, structures corresponding to the structures described with the first to eighth preferred embodiments shall be provided with the same reference signs and description thereof shall be omitted.

Referring to FIG. 17 and FIG. 18, the SiC semiconductor device 1I, as with the SiC semiconductor device 1A according to the first preferred embodiment, includes the SiC chip 2, the n-type base region 6, the n-type buffer region 7, the n-type drift region 8, and the functional device 9. As in the case of the first preferred embodiment, the SiC chip 2 has the off angle θ and the off direction D. In this embodiment, the SiC semiconductor device 1I includes a plurality of p-type column regions 19 that are formed inside the drift region 8. The column regions 19 may be referred to as “impurity regions.”

The column regions 19 are formed using portions of the SiC chip 2. In plan view, the column regions 19 are formed inside the drift region 8 at intervals inward from the peripheral edges of the SiC chip 2. In this embodiment, the column regions 19 are respectively formed as bands that extend in a first direction X (a-axis direction) and are aligned at intervals in a second direction Y (m-axis direction) in plan view. That is, the column regions 19 are formed as stripes extending in the off direction D (=first direction X) in plan view.

As a matter of course, the column regions 19 may be respectively formed as bands that are aligned at intervals in the first direction X (a-axis direction) and extend in the second direction Y (m-axis direction) in plan view instead. That is, the column regions 19 may instead be formed as stripes extending in a direction (=second direction Y) orthogonal to the off direction D in plan view. Also, the column regions 19 may be formed in a lattice intersecting in the first direction X and the second direction Y instead. Also, the column regions 19 may be formed as dots at intervals in the first direction X and the second direction Y instead.

The column regions 19 may be aligned at intervals (column pitch) of not less than 0.5 μm and not more than 10 μm. The column regions 19 are preferably aligned at substantially equal intervals. The column regions 19 may each have a width (column width) of not less than 0.5 μm and not more than 10 μm. Preferably, the column regions 19 each have a substantially equal width.

The column regions 19 each form a pn-junction with the drift region 8. Specifically, the column regions 19 are formed as columns extending in the thickness direction of the drift region 8 in sectional view and each form a pn-junction portion along the thickness direction with the drift region 8. Preferably, the column regions 19 each extend from the first main surface 3 such as to traverse an intermediate portion MID. The column regions 19 are each formed at an interval to the first main surface 3 side from a bottom portion of the drift region 8 (that is, the buffer region 7). The column regions 19 oppose the buffer region 7 across a region at a bottom portion side of the drift region 8 that is of comparatively low concentration.

The column regions 19 each form a super junction structure with the drift region 8. That is, the column regions 19 each form the pn-junction portion that extends in the thickness direction of the drift region 8 such as to spread a depletion layer in a width direction of the drift region 8. The column regions 19 are preferably aligned at intervals in a mode where the depletion layer spreading from one column region 19 is connected to the depletion layer spreading from another adjacent column region 19.

The column regions 19 are formed in a mode of replacing the n-type impurity concentration of the drift region 8 with a p-type impurity concentration by a trivalent element. That is, the column regions 19 each have, in addition to the pentavalent elements constituting the drift region 8 (basal concentration CA and added concentration CB), a trivalent element introduced at a p-type impurity concentration that exceeds the n-type impurity concentration of the drift region 8.

The column regions 19 include a trivalent element other than boron and have an impurity concentration that is adjusted by the trivalent element other than boron. The column regions 19 preferably include at least one among aluminum, gallium, and indium. The column regions 19 have an impurity concentration that is adjusted such as to increase (specifically, increase gradually) toward the first main surface 3.

The column regions 19 preferably have a concentration gradient of the p-type impurity that is proportional to the concentration gradient of the drift region 8. The column regions 19 preferably have an impurity concentration that is adjusted such as to maintain a charge balance with the drift region 8. To “maintain a charge balance” means that the depletion layers spreading from the column regions 19 are respectively connected in regions between the plurality of pairs of adjacent column regions 19.

For example, if the column width is x (0<x) times the column pitch, the column regions 19 maintain a charge balance when the impurity concentration of the columns is 1/x times the impurity concentration of the drift region 8. If the column width is equal to the column pitch, the column regions 19 preferably have a concentration gradient of the p-type impurity that increases from the second concentration C2 to the third concentration C3 in correspondence to the drift region 8 having the concentration gradient that increases from the second concentration C2 to the third concentration C3.

In this embodiment, the functional device 9 is formed using the drift region 8 and the column regions 19. That is, the SiC semiconductor device 1I includes the functional device 9 of a super junction type.

As described above, the SiC semiconductor device 1I includes the SiC chip 2, the n-type drift region 8, and the p-type column regions (impurity regions) 19. The SiC chip 2 has the first main surface 3. The drift region 8 is formed in the surface layer portion of the first main surface 3 and has the impurity concentration that is adjusted by at least two types of pentavalent elements. The column regions 19 are formed inside the drift region 8 such as to form the pn-junction portions with the drift region 8. With this structure, the same effects as the effects described for the SiC semiconductor device 1A are exhibited. Also, With this structure, the pn-junction portions can be formed appropriately between the drift region 8 and the column regions 19. The SiC semiconductor device 1I that can be improved in electrical characteristics (for example, a withstand voltage due to the column regions 19) can thus be provided.

From another perspective, the SiC semiconductor device 1I includes the SiC chip 2, the n-type drift region 8, and the p-type column regions (impurity regions) 19. The SiC chip 2 has the first main surface 3. The drift region 8 is formed in the surface layer portion of the first main surface 3. The column regions 19 are formed inside the drift region 8 such as to form the pn-junction portions with the drift region 8 and have the impurity concentration that is adjusted by the trivalent element other than boron.

Boron has a property of being difficult to introduce into a deep region of the SiC chip 2. Therefore, by adjusting the impurity concentration of the column regions 19 by the trivalent element other than boron, the column regions 19 having the impurity concentration that is reduced in variation with respect to a target concentration can be formed. The pn-junction portions can thereby be formed appropriately between the drift region 8 and the column regions 19. The SiC semiconductor device 1I that can be improved in electrical characteristics (for example, the withstand voltage due to the column regions 19) can thus be provided.

The drift region 8 preferably has a concentration distribution that increases toward the first main surface 3. The column regions 19 preferably have a concentration distribution that increases toward the first main surface 3. The drift region 8 preferably includes at least one type of trivalent element among nitrogen, arsenic, and antimony. The column regions 19 preferably include at least one type of trivalent element among aluminum, gallium, and indium.

The column regions 19 preferably extend in the thickness direction inside the drift region 8 such as to form the super junction structure by the pn-junction portions with the drift region 8. The column regions 19 preferably traverse the intermediate portion MID. The column regions 19 are preferably formed at intervals to the first main surface 3 side from the bottom portion of the drift region 8.

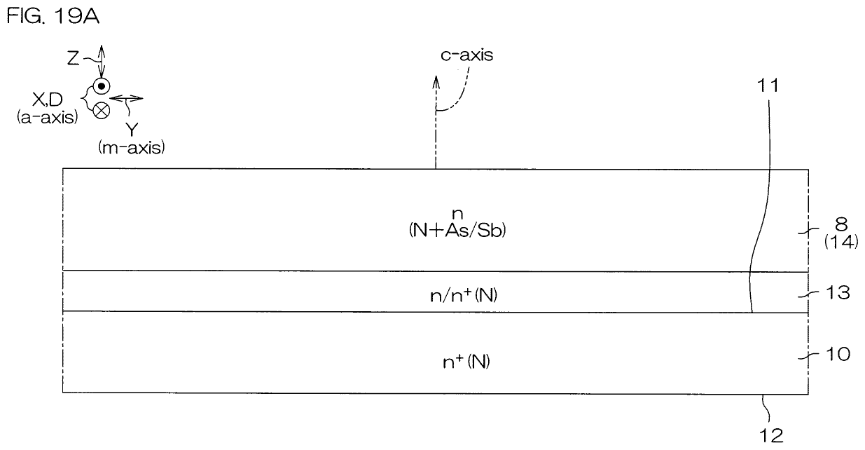

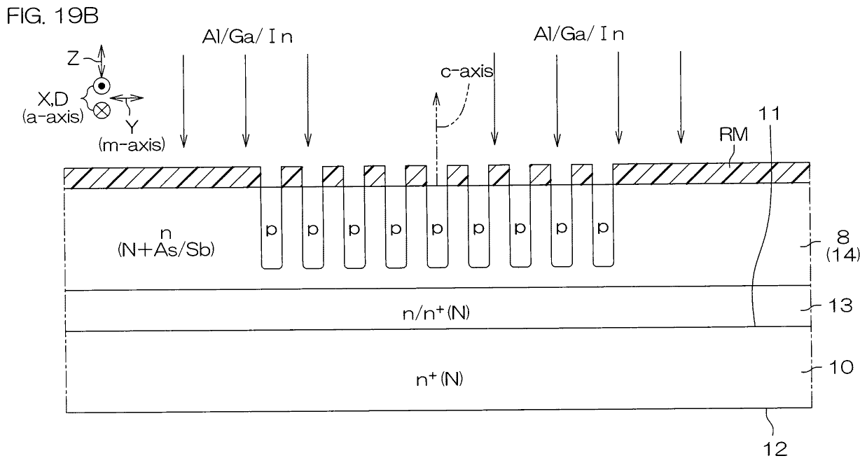

FIG. 19A and FIG. 19B are sectional views of a method for manufacturing the SiC semiconductor device 1I shown in FIG. 17. Referring to FIG. 19A, the drift region 8 is formed in the second SiC epitaxial layer 14 through the same steps as in FIG. 4A to FIG. 4D.

Referring to FIG. 19B, a resist mask RM having a predetermined pattern is formed on the second SiC epitaxial layer 14. The resist mask RM exposes regions of the drift region 8 in which the column regions 19 are to be formed and covers a region besides these. Next, the trivalent element (p-type impurity) is implanted into the drift region 8 by an ion implantation method via the resist mask RM to form the p-type column regions 19 having the target concentration.

In this step, the trivalent element is implanted into the drift region 8 such that the impurity concentration increases (specifically, increases gradually) in the crystal growth direction. The ion implantation method in this step is a channeling implantation method. With the channeling implantation method, the trivalent element is implanted in regions at a main surface (crystal growth surface) side and regions at the SiC wafer 10 side of the second SiC epitaxial layer 14 with respect to an intermediate portion of the second SiC epitaxial layer 14.

An implantation depth of the trivalent element with respect to the drift region 8 is adjusted precisely by adjusting an implantation energy of the trivalent element, an implantation temperature of the second impurity, an implantation angle of the second impurity, etc. The implantation energy of the trivalent element may be adjusted in a range of not less than 10 keV and not more than 1000 keV (preferably, not more than 100 keV). The implantation temperature of the trivalent element may be adjusted in a range of not less than 300° C. and not more than 1000° C.

The implantation angle of the trivalent element is set in a range of ±5° with the crystal axis (=c-axis) of the SiC monocrystal as a basis (=0°). The implantation angle of the trivalent element is preferably set in a range of ±2°. In this embodiment, the second SiC epitaxial layer 14 (SiC wafer 10) has the off angle 9 that is inclined in the predetermined off direction D. Therefore, with the channeling implantation method, the implantation angle of the trivalent element with respect to the second SiC epitaxial layer 14 or an inclination angle of the second SiC epitaxial layer 14 with respect to an implantation direction of the trivalent element is adjusted in accordance with the off direction D and the off angle θ.

In this embodiment, the column regions 19 that extend in the off direction D (=first direction X) are formed. With this structure, the implantation angle of the trivalent element is an inclination angle with respect to the off direction D and therefore a vector component of the trivalent element that is implanted into the second SiC epitaxial layer 14 is oriented along the off direction D. The trivalent element is thus implanted along a line extending in the off direction D in plan view and is implanted substantially vertically with respect to the c-plane of the SiC monocrystal in a sectional view in a direction orthogonal to the off direction D.

The trivalent element used in the channeling implantation method may be at least one among boron, aluminum, gallium, and indium. However, boron has a property of being difficult to implant into a deep region of the second SiC epitaxial layer 14 by the channeling implantation method. The trivalent element used in the channeling implantation method is therefore preferably a trivalent element other than boron.

After the implantation of the trivalent element, the trivalent element is electrically activated and lattice defects, etc., that formed in the second SiC epitaxial layer 14 are repaired at the same time by an annealing method. An annealing temperature of the second SiC epitaxial layer 14 may be not less than 500° C. and not more than 2000° C. The activation of the trivalent element may be performed at the same time as the activation of the pentavalent elements of the drift region 8. The trivalent element is thereby formed. Thereafter, the functional device 9 that uses the drift region 8 and the column regions 19 is formed at the main surface (crystal growth surface) side of the second SiC epitaxial layer 14. The SiC semiconductor device 1I is manufactured through steps including the above.

The method for manufacturing the SiC semiconductor device 1I described above includes a first step of preparing the second SiC epitaxial layer 14, a second step of forming the n-type drift region 8, and a third step of forming the p-type column regions 19. In the first step, the n-type second SiC epitaxial layer 14 of low concentration is prepared. Specifically, the impurity concentration of the second SiC epitaxial layer 14 is less than the target concentration of the drift region 8. In the second step, the pentavalent elements (n-type impurity) are implanted into the second SiC epitaxial layer 14 by the ion implantation method to form the n-type drift region 8 having the target concentration. In the third step, the trivalent element (p-type impurity) is implanted into the second SiC epitaxial layer 14 by the ion implantation method to form the p-type column regions 19 that form the pn-junction portions with the drift region 8.

With this manufacturing method, the same effects as the effects described for the method for manufacturing the SiC semiconductor device 1A are exhibited. Also, by the method for manufacturing the SiC semiconductor device 1I, the pn-junction portions can be formed appropriately between the drift region 8 and the column regions 19. The SiC semiconductor device 1I that can be improved in electrical characteristics (for example, the withstand voltage due to the column regions 19) can thus be manufactured and provided.

From another perspective, the method for manufacturing the SiC semiconductor device II includes a first step of preparing the second SiC epitaxial layer 14 in which the n-type drift region 8 is formed and a second step of forming the p-type column regions 19. In the second step, the trivalent element (p-type impurity) other than boron is implanted into the second SiC epitaxial layer 14 by the ion implantation method to form the p-type column regions 19 that form the pn-junction portions with the drift region 8.

Boron has a property of being difficult to introduce into a deep region of the second SiC epitaxial layer 14. Therefore, by adjusting the impurity concentration of the column regions 19 by the trivalent element other than boron, variations in the impurity concentration of the column regions 19 with respect to the target concentration can be suppressed. The pn-junction portions can thereby be formed appropriately between the drift region 8 and the column regions 19. The SiC semiconductor device 1I that can be improved in electrical characteristics (for example, the withstand voltage due to the column regions 19) can thus be manufactured and provided.

In the method for manufacturing the SiC semiconductor device 1I, the second SiC epitaxial layer 14 having the impurity concentration that is adjusted by a first impurity may be prepared. In this case, the drift region 8 may be formed by implanting a second impurity that differs from the first impurity into the second SiC epitaxial layer 14. The first impurity is preferably a pentavalent element other than phosphorus. The first impurity is preferably nitrogen. The second impurity is preferably a pentavalent element other than phosphorus. The second impurity is preferably at least one among arsenic and antimony.

In the step of forming the column regions 19, the channeling implantation method of implanting the trivalent element along the crystal axis of the second SiC epitaxial layer 14 may be performed. The trivalent element used in the channeling implantation method is preferably a trivalent element other than boron. The trivalent element used in the channeling implantation method may be at least one among aluminum, gallium, and indium.

The trivalent element is preferably implanted into the second SiC epitaxial layer 14 at the implantation angle of not more than ±5° on the basis of the crystal axis of the SiC monocrystal. The crystal axis of the SiC monocrystal is preferably the c-axis. The second SiC epitaxial layer 14 preferably has the off angle θ of not more than 10° with respect to the c-plane of the SiC monocrystal. The off angle θ preferably has the off direction D that is oriented along the a-axis direction of the SiC monocrystal.

Preferably with the channeling implantation method, the column regions 19 that extend along the off direction D are formed. By this step, a vector component of the trivalent element that is implanted is oriented along the off direction D. The trivalent element is thereby implanted on a line extending in the off direction D and substantially vertically with respect to the c-plane of the SiC monocrystal, and therefore, the column regions 19 can be formed appropriately.

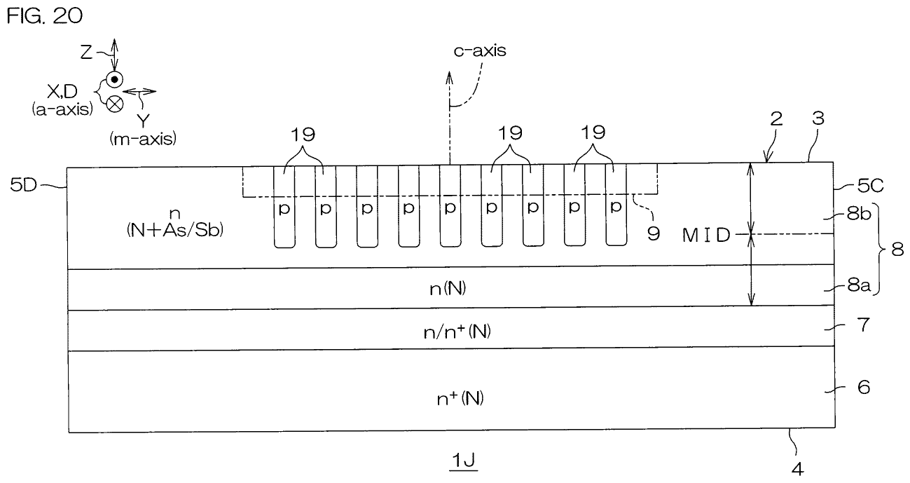

FIG. 20 corresponds to FIG. 18 and is a plan view of an SiC semiconductor device 1J according to a tenth preferred embodiment. In the following, structures corresponding to the structures described with the first to ninth preferred embodiments shall be provided with the same reference signs and description thereof shall be omitted.

Referring to FIG. 20, the SiC semiconductor device 1J, as with the SiC semiconductor device 1B according to the second preferred embodiment, includes the SiC chip 2, the n-type base region 6, the n-type buffer region 7, the n-type drift region 8, and the functional device 9. The drift region 8 includes the first region 8a and the second region 8b. In this embodiment, the SiC semiconductor device 1J includes a plurality of p-type column regions 19 that are formed inside the drift region 8.

The column regions 19 are formed in the same mode in plan view as the column regions 19 according to the ninth preferred embodiment. In this embodiment, the column regions 19 are each formed inside the second region 8b of the drift region 8 such as to form a pn-junction with the second region 8b. Specifically, the column regions 19 are formed as columns extending in the thickness direction of the second region 8b in sectional view and each form, with the second region 8b, a pn-junction portion that extends along the thickness direction.

Preferably, the column regions 19 each extend from the first main surface 3 such as to traverse an intermediate portion MID. Preferably, the column regions 19 are each formed at an interval to the first main surface 3 side from the first region 8a and each oppose the buffer region 7 across the first region 8a and a portion of the second region 8b. Preferably, lower end portions of the column regions 19 are positioned in a region between the intermediate portion MID and the first region 8a.

The column regions 19 each form a super junction structure with the second region 8b. That is, the column regions 19 each form the pn-junction portion that extends in the thickness direction of the second region 8b such as to spread a depletion layer in a width direction of the second region 8b. The column regions 19 are preferably aligned at intervals in a mode where the depletion layer spreading from one column region 19 is connected to the depletion layer spreading from another adjacent column region 19.

In this embodiment, the column regions 19 are formed in a mode of replacing (offsetting) the n-type impurity concentration of the second region 8b with a p-type impurity concentration by a trivalent element. That is, the column regions 19 each have, in addition to the pentavalent elements constituting the second region 8b (basal concentration CA and added concentration CB), a trivalent element introduced at a p-type impurity concentration that exceeds the n-type impurity concentration of the second region 8b. The column regions 19 preferably have a concentration gradient of the p-type impurity that is proportional to the concentration gradient of the second region 8b. The column regions 19 preferably have an impurity concentration that is adjusted such as to maintain a charge balance with the second region 8b.

In this embodiment, the functional device 9 is formed using the drift region 8 and the column regions 19. That is, the SiC semiconductor device 1J includes the functional device 9 of a super junction type.

Even with the SiC semiconductor device 1J described above, the same effects as the effects described for the SiC semiconductor device 1I according to the ninth preferred embodiment are exhibited.

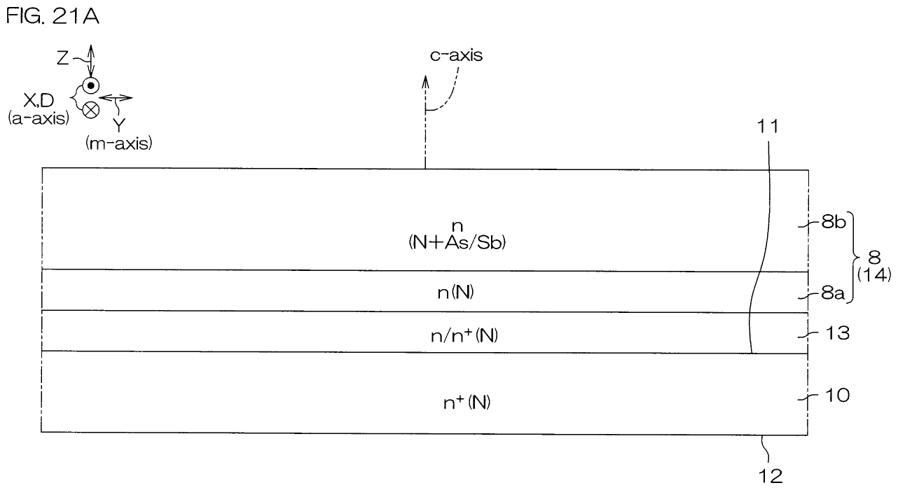

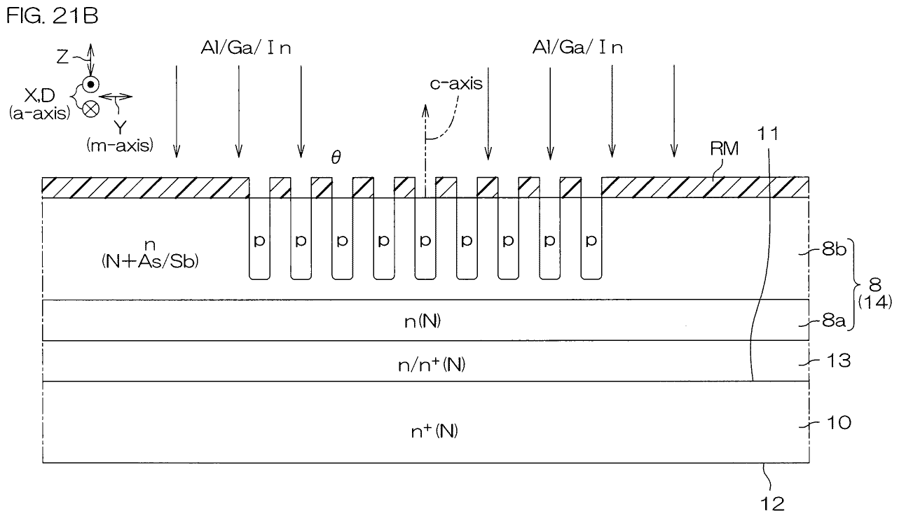

FIG. 21A and FIG. 21B are sectional views of a method for manufacturing the SiC semiconductor device 1J shown in FIG. 20. Referring to FIG. 21A, the drift region 8 is formed in the second SiC epitaxial layer 14 through the same steps as in FIG. 4A to FIG. 4C and FIG. 8A and FIG. 8B. The drift region 8 includes the first region 8a and the second region 8b.

Referring to FIG. 21B, a resist mask RM having a predetermined pattern is formed on the second SiC epitaxial layer 14. The resist mask RM exposes regions of the drift region 8 in which the column regions 19 are to be formed and covers a region besides these. Next, the trivalent element (p-type impurity) is implanted into the drift region 8 by an ion implantation method (in this embodiment, a channeling implantation method) via the resist mask RM to form the p-type column regions 19 having the target concentration.

In this step, the trivalent element other than boron is implanted to a thickness direction intermediate portion of the second region 8b. Specifically, the trivalent element is implanted into the second region 8b at an interval to the first main surface 3 side from the first region 8a. In this embodiment, the trivalent element other than boron is at least one among aluminum, gallium, and indium.

Even by the method for manufacturing the SiC semiconductor device 1J described above, the same effects as the effects described for the method for manufacturing the SiC semiconductor device II according to the ninth preferred embodiment are exhibited.

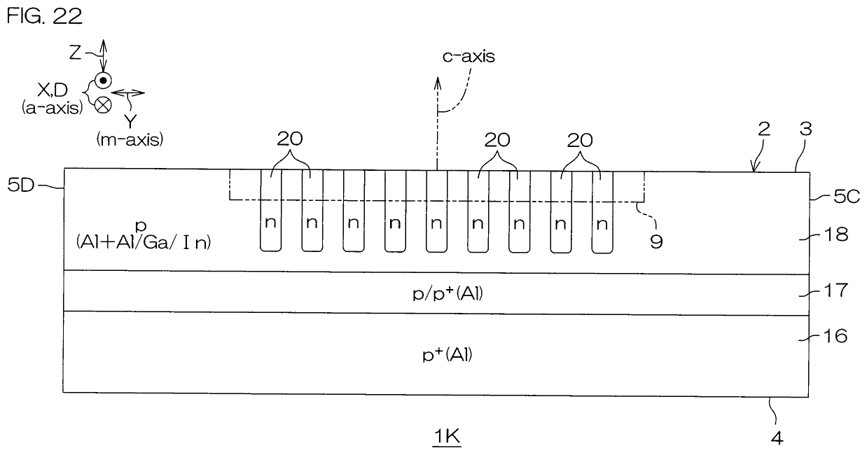

FIG. 22 corresponds to FIG. 18 and is a sectional view of an SiC semiconductor device 1K according to an eleventh preferred embodiment. In the following, structures corresponding to the structures described with the first to tenth preferred embodiments shall be provided with the same reference signs and description thereof shall be omitted.

Referring to FIG. 22, the SiC semiconductor device 1K, as with the SiC semiconductor device 1C according to the third preferred embodiment, includes the SiC chip 2, the p-type base region 16, the p-type buffer region 17, the p-type drift region 18, and the functional device 9. In this embodiment, the SiC semiconductor device 1K includes a plurality of n-type column regions 20 that are formed inside the drift region 18. The column regions 20 may be referred to as “impurity regions.”

The column regions 20 are formed using portions of the SiC chip 2. With the exception of including a pentavalent element in place of a trivalent element, the column regions 20 are formed in the same mode as the column regions 19 according to the ninth preferred embodiment. In this embodiment, the column regions 20 are formed in a mode of replacing the p-type impurity concentration of the drift region 18 with an n-type impurity concentration by a pentavalent element. That is, the column regions 20 each have, in addition to the trivalent elements constituting the drift region 18 (basal concentration CA and added concentration CB), a pentavalent element introduced at an n-type impurity concentration that exceeds the p-type impurity concentration of the drift region 18.

The column regions 20 include a pentavalent element other than phosphorus and nitrogen and have an impurity concentration that is adjusted by the pentavalent element other than phosphorus and nitrogen. The column regions 20 preferably include at least one among arsenic and antimony. The column regions 20 have an impurity concentration that is adjusted such as to increase (specifically, increase gradually) toward the first main surface 3. The column regions 20 preferably have a concentration gradient of the n-type impurity that is proportional to the concentration gradient of the drift region 18. The column regions 20 preferably have an impurity concentration that is adjusted such as to maintain a charge balance with the drift region 18.

In this embodiment, the functional device 9 is formed using the drift region 18 and the column regions 20. That is, the SiC semiconductor device 1K includes the functional device 9 of a super junction type.

Even with the SiC semiconductor device 1K described above, the same effects as the effects described for the SiC semiconductor device 1I according to the ninth preferred embodiment are exhibited. The SiC semiconductor device 1K is manufactured by replacing the pentavalent elements in the method for manufacturing the SiC semiconductor device 1I according to the ninth preferred embodiment (FIG. 4A to FIG. 4D and FIG. 19A and FIG. 19B) by predetermined trivalent elements. Therefore, even with the method for manufacturing the SiC semiconductor device 1K, the same effects as those described for the method for manufacturing the SiC semiconductor device II according to the ninth preferred embodiment are exhibited.

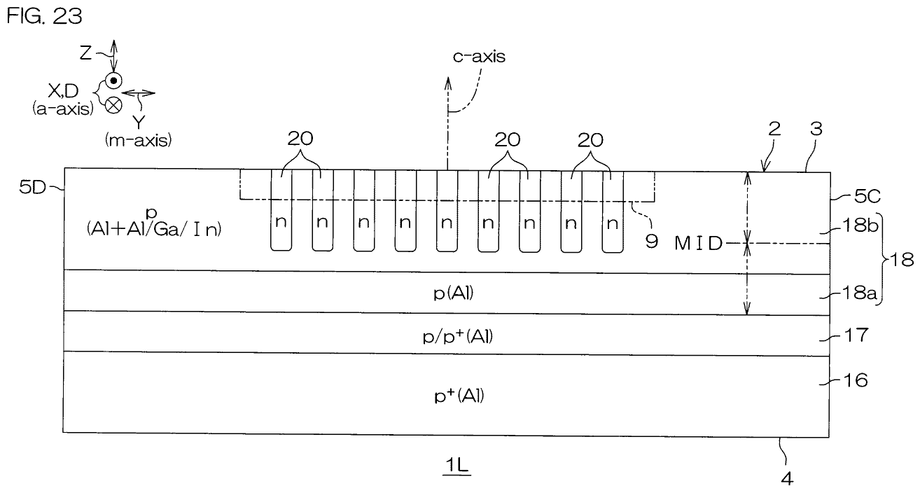

FIG. 23 corresponds to FIG. 18 and is a plan view of an SiC semiconductor device 1L according to a twelfth preferred embodiment. In the following, structures corresponding to the structures described with the first to eleventh preferred embodiments shall be provided with the same reference signs and description thereof shall be omitted.

Referring to FIG. 20, the SiC semiconductor device 1L, as with the SiC semiconductor device 1D according to the fourth preferred embodiment, includes the SiC chip 2, the p-type base region 16, the p-type buffer region 17, the p-type drift region 18, and the functional device 9. The drift region 18 includes the first region 18a and the second region 18b. In this embodiment, the SiC semiconductor device 1L includes a plurality of n-type column regions 20 that are formed inside the drift region 18.

With the exception of including a pentavalent element in place of a trivalent element, the column regions 20 are formed in the same mode as the column regions 19 according to the tenth preferred embodiment (ninth preferred embodiment). Also, the column regions 20 are formed in the same mode as in the eleventh preferred embodiment. In this embodiment, the column regions 20 are each formed inside the second region 18b such as to form a pn-junction with the second region 18b. Specifically, the column regions 20 are formed as columns extending in the thickness direction of the second region 18b in sectional view and each form a pn-junction portion that extends along the thickness direction of the second region 18b.

Preferably, the column regions 20 each extend from the first main surface 3 such as to traverse an intermediate portion MID. Preferably, the column regions 20 are each formed at an interval to the first main surface 3 side from the first region 18a and each oppose the buffer region 17 across the first region 18a and a portion of the second region 18b. Preferably, lower end portions of the column regions 20 are positioned in a region between the intermediate portion MID and the first region 18a.

In this embodiment, the column regions 20 are formed in a mode of replacing (offsetting) the p-type impurity concentration of the second region 18b with an n-type impurity concentration by a pentavalent element. That is, the column regions 20 each have, in addition to the trivalent elements constituting the second region 18b (basal concentration CA and added concentration CB), a pentavalent element introduced at an n-type impurity concentration that exceeds the p-type impurity concentration of the second region 18b.

The column regions 20 each form a super junction structure with the second region 18b. That is, the column regions 20 each form the pn-junction portion that extends in the thickness direction of the second region 18b such as to spread a depletion layer in a width direction of the second region 18b. The column regions 20 are preferably aligned at intervals in a mode where the depletion layer spreading from one column region 20 is connected to the depletion layer spreading from another adjacent column region 20. The column regions 20 preferably have a concentration gradient of the n-type impurity that is at least proportional to the concentration gradient of the second region 18b. The column regions 20 preferably have an impurity concentration that is adjusted such as to maintain a charge balance with the second region 18b.

In this embodiment, the functional device 9 is formed using the drift region 18 and the column regions 20. That is, the SiC semiconductor device 1L includes the functional device 9 of a super junction type.

Even with the SiC semiconductor device 1L described above, the same effects as the effects described for the SiC semiconductor device 1J according to the tenth preferred embodiment are exhibited. The SiC semiconductor device 1L is manufactured by replacing the pentavalent elements in the method for manufacturing the SiC semiconductor device 1J according to the tenth preferred embodiment (FIG. 4A to FIG. 4D and FIG. 21A and FIG. 21B) by predetermined trivalent elements. Therefore, even with the method for manufacturing the SiC semiconductor device 1L, the same effects as those described for the method for manufacturing the SiC semiconductor device 1J according to the tenth preferred embodiment are exhibited.

Configuration examples of the functional device 9 that can be applied to the first to twelfth preferred embodiments shall now be described. In the following, specific configuration examples of the functional device 9 shall be described using any one among the SiC semiconductor devices 1A to 1L according to the first to twelfth preferred embodiments.

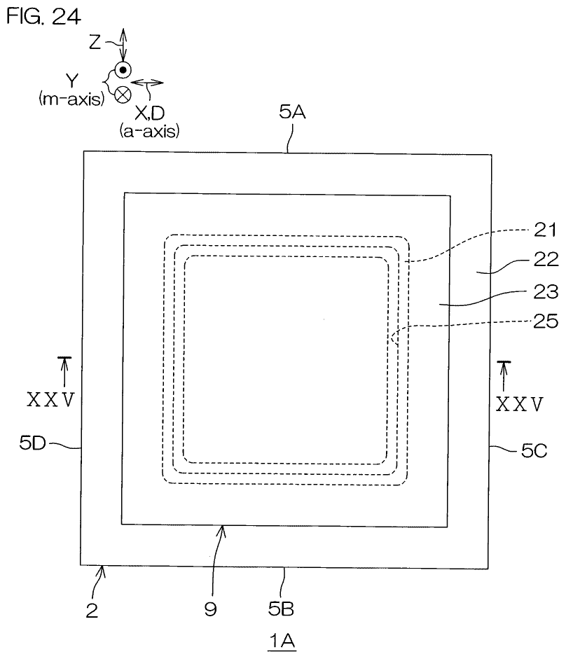

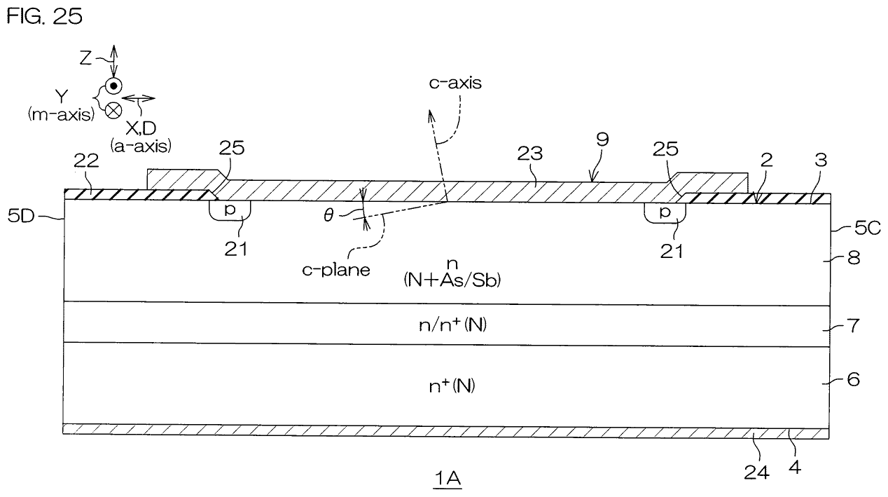

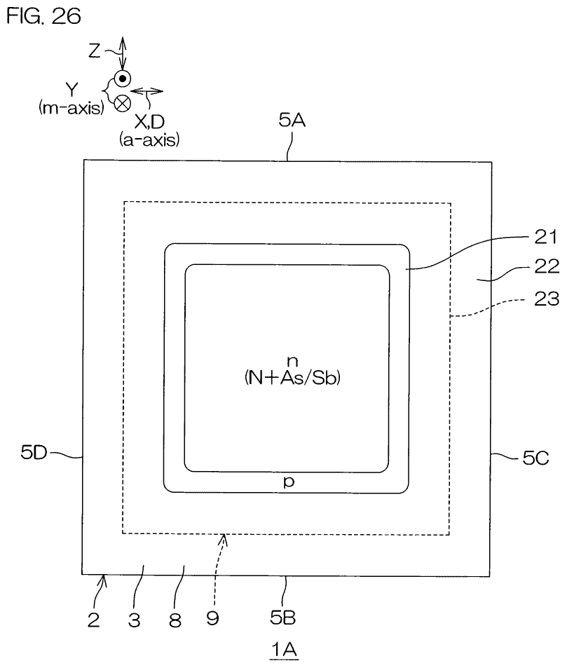

FIG. 24 is a plan view of a structure with which the functional device 9 according to a first configuration example is applied to the SiC semiconductor device 1A according to the first preferred embodiment. FIG. 25 is a sectional view taken along line XXV-XXV shown in FIG. 24. FIG. 26 is a plan view of the SiC chip 2 shown in FIG. 25. In the following, structures corresponding to structures described with the first preferred embodiment shall be provided with the same reference signs and description thereof shall be omitted.

Referring to FIG. 24 to FIG. 26, the SiC semiconductor device 1A includes the SiC chip 2, the n-type base region 6, the n-type buffer region 7, the n-type drift region 8, and the functional device 9. In this embodiment, the functional device 9 is an SiC-SBD. In this embodiment, the base region 6 is formed as a cathode region of the SiC-SBD. The SiC semiconductor device 1A includes a p-type guard region 21, an insulating film 22, a first main surface electrode 23, and a second main surface electrode 24.

The guard region 21 is formed in a surface layer portion of the drift region 8 at intervals inward from peripheral edges of the first main surface 3 (first to fourth side surfaces 5A to 5D). The guard region 21 extends as a band along the peripheral edges of the first main surface 3 in plan view. In this embodiment, the guard region 21 is formed to an annular shape that surrounds an inner portion of the first main surface 3 in plan view. The guard region 21 is thereby formed as a guard ring region. The guard region 21 has an inner edge portion at the inner portion side of the first main surface 3 and an outer edge portion at the peripheral edge side of the first main surface 3. A p-type impurity of the guard region 21 may be activated or may be non-activated.

The insulating film 22 covers the first main surface 3. Specifically, the insulating film 22 covers a region between the peripheral edges of the first main surface 3 and the guard region 21 such as to cover the outer edge portion of the guard region 21. The insulating film 22 has an opening 25 that exposes the inner portion of the first main surface 3 and the inner edge portion of the guard region 21.

The first main surface electrode 23 covers the first main surface 3. Specifically, the first main surface electrode 23 enters into the opening 25 from above the insulating film 22 and coves the first main surface 3 inside the opening 25. The first main surface electrode 23 is electrically connected to the drift region 8 and the guard region 21 inside the opening 25. In this embodiment, the first main surface electrode 23 forms a Schottky junction with the drift region 8. The second main surface electrode 24 covers the second main surface 4. Specifically, the second main surface electrode 24 covers substantially an entirety of the second main surface 4. The second main surface electrode 24 forms an ohmic contact with the base region 6.

With the structure described above, the SiC semiconductor device 1A having the SiC-SBD that is improved in electrical characteristics by the drift region 8 can be provided. As a matter of course, the structure of the functional device 9 (SiC-SBD) according to the first configuration example can be applied to any one of the first to twelfth preferred embodiments other than the first preferred embodiment as well.

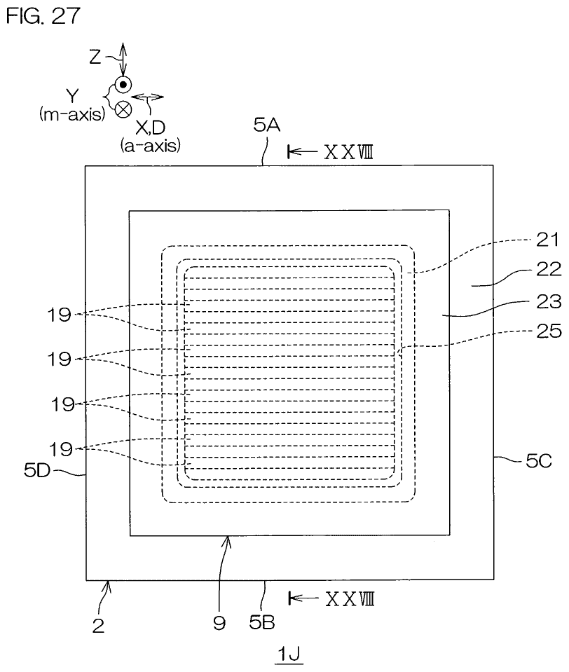

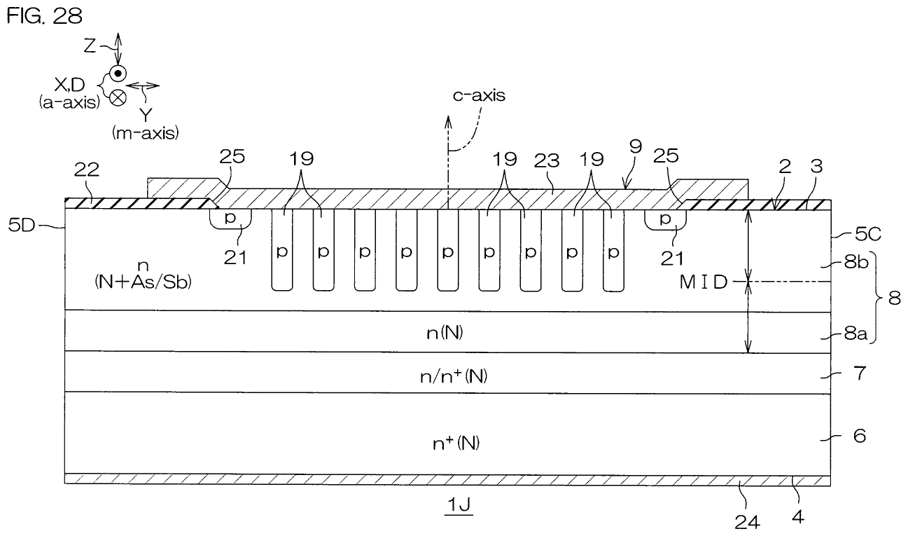

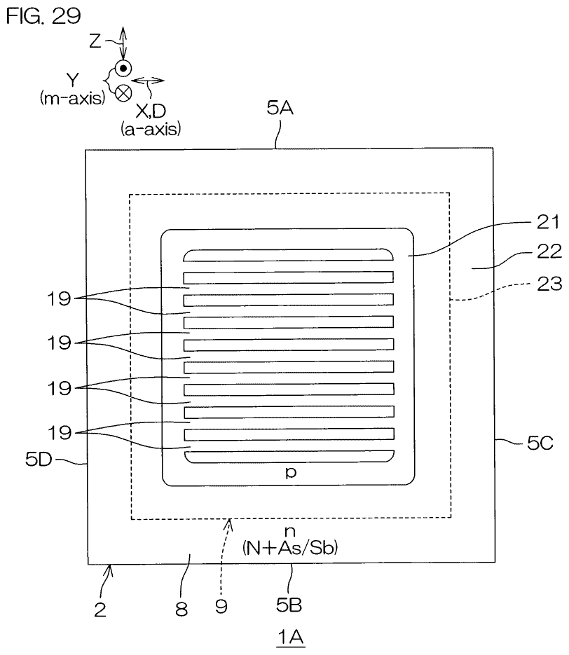

FIG. 27 is a plan view of a structure with which the functional device 9 according to a second configuration example is applied to the SiC semiconductor device 1J according to the tenth preferred embodiment. FIG. 28 is a sectional view taken along line XXVIII-XXVIII shown in FIG. 27. FIG. 29 is a plan view of the SiC chip 2 shown in FIG. 28. In the following, structures corresponding to structures described with the tenth preferred embodiment shall be provided with the same reference signs and description thereof shall be omitted.

Referring to FIG. 27 to FIG. 29, the SiC semiconductor device 1J includes the SiC chip 2, the n-type base region 6, the n-type buffer region 7, the n-type drift region 8, the p-type column regions 19, and the functional device 9. The drift region 8 includes the first region 8a and the second region 8b. In this embodiment, the functional device 9 is a super junction-type SiC-SBD. In this embodiment, the base region 6 is formed as a cathode region of the SiC-SBD.

As with the functional device 9 according to the first configuration example (see FIG. 24 to FIG. 26), the SiC semiconductor device 1J includes the p-type guard region 21, the insulating film 22, the first main surface electrode 23, and the second main surface electrode 24. Points of difference with respect to the functional device 9 according to the first configuration example (see FIG. 24 to FIG. 26) shall be described below.

In this embodiment, the guard region 21 is formed shallower than the column regions 19 and is formed at a depth position at the first main surface 3 side with respect to bottom portions of the columns. The guard region 21 is preferably formed in a region further to the first main surface 3 side than intermediate portions of the column regions 19. The guard region 21 may be connected to both end portions in a length direction of the column regions 19. In this embodiment, the insulating film 22 has the opening 25 that exposes the column regions 19 and the inner edge portion of the guard region 21 in the inner portion of the first main surface 3. The first main surface electrode 23 is electrically connected to the drift region 8, the column regions 19, and the guard region 21 inside the opening 25.

With the structure described above, the SiC semiconductor device 1J having the super junction type SiC-SBD that is improved in electrical characteristics by the drift region 8 and the column regions 19 can be provided. As a matter of course, the structure of the functional device 9 (super junction type SiC-SBD) according to the second configuration example can be applied to any one of the ninth to twelfth preferred embodiments other than the tenth preferred embodiment as well.

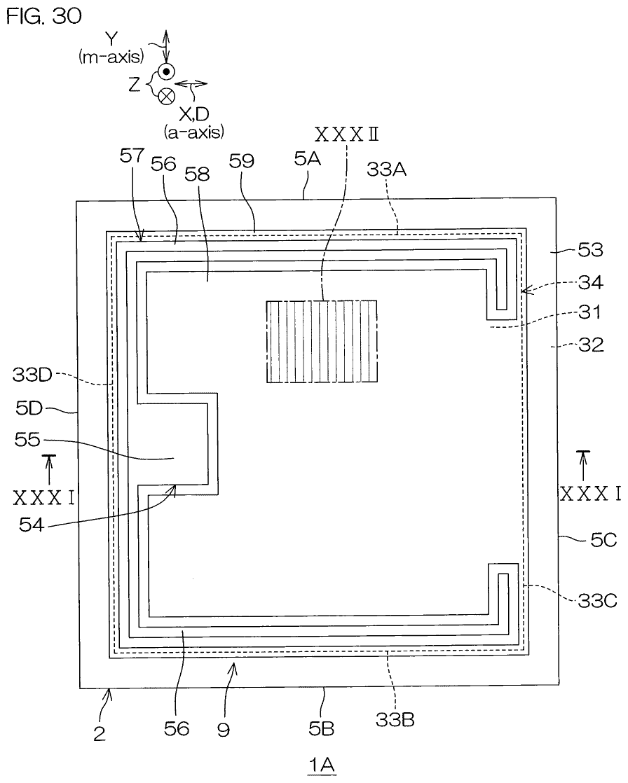

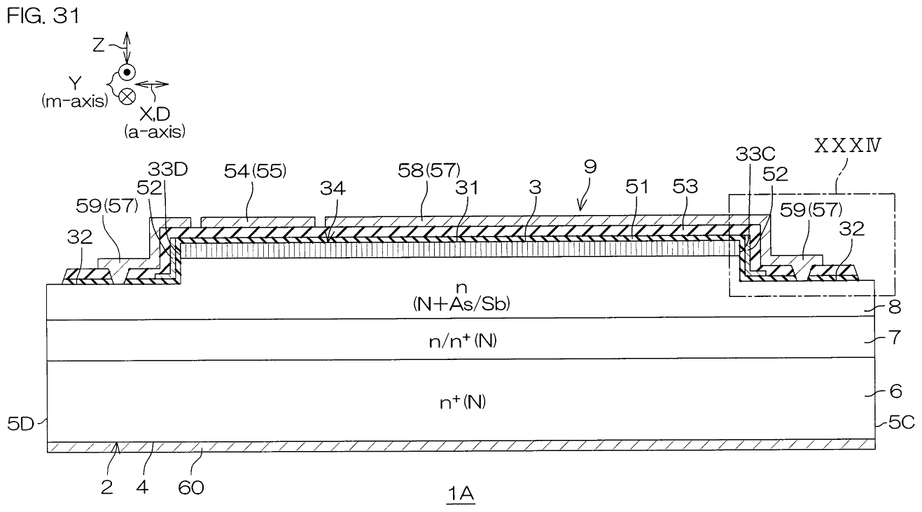

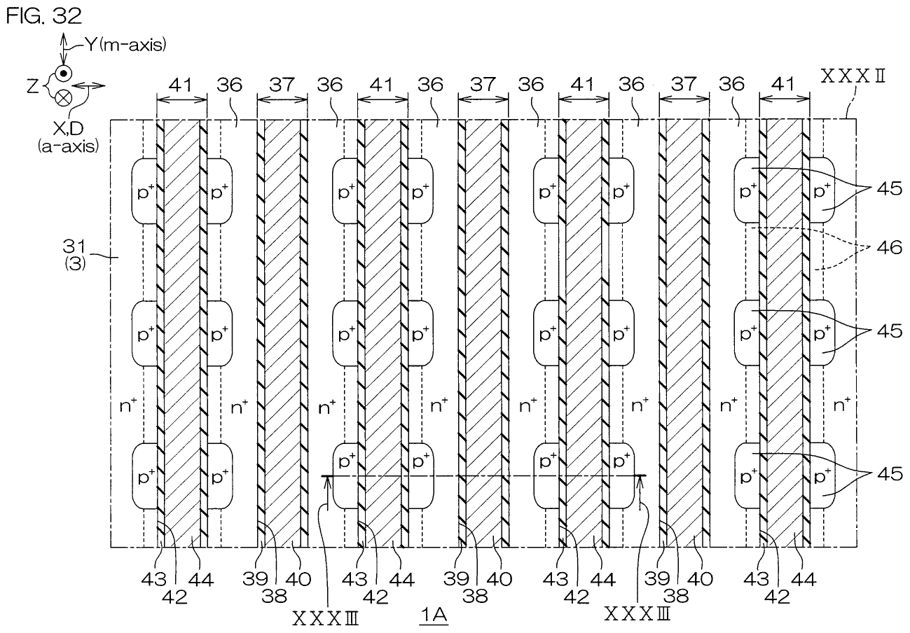

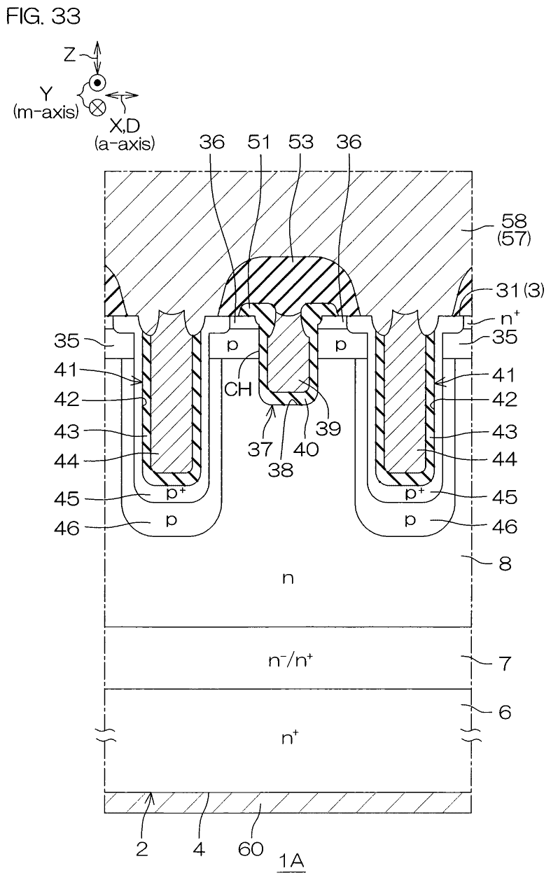

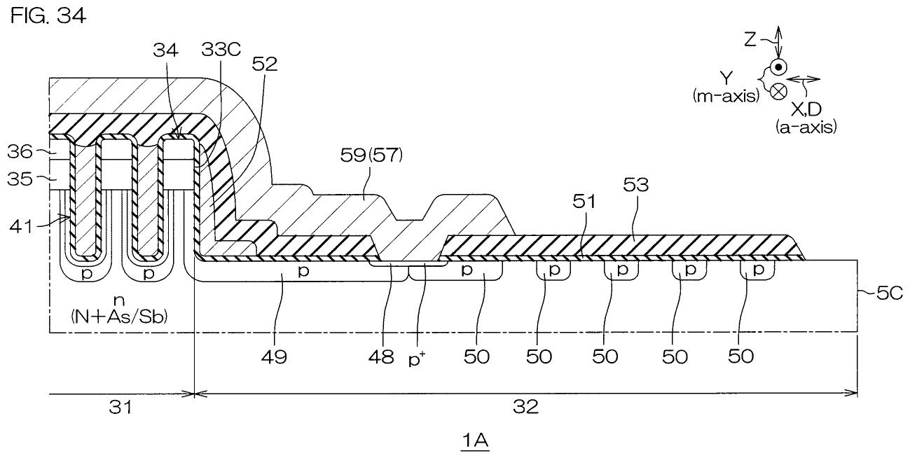

FIG. 30 is a plan view of a structure with which the functional device 9 according to a third configuration example is applied to the SiC semiconductor device 1A according to the first preferred embodiment. FIG. 31 is a sectional view taken along line XXXI-XXXI shown in FIG. 30. FIG. 32 is an enlarged view of a region XXXII shown in FIG. 30. FIG. 33 is a sectional view taken along line XXXII-XXXII shown in FIG. 32. FIG. 34 is an enlarged view of a region XXXIV shown in FIG. 31. In the following, structures corresponding to structures described with the first preferred embodiment shall be provided with the same reference signs and description thereof shall be omitted.

Referring to FIG. 30 to FIG. 34, the SiC semiconductor device 1A includes the SiC chip 2, the n-type base region 6, the n-type buffer region 7, the n-type drift region 8, and the functional device 9. In this embodiment, the functional device 9 is a trench gate type SiC-MISFET. In this embodiment, the base region 6 is formed as a drain region of the SiC-MISFET.

The SiC semiconductor device 1A has an active surface 31, an outside surface 32, and first to fourth connecting surfaces 33A to 33D that are formed at the first main surface 3. The active surface 31, the outside surface 32, and the first to fourth connecting surfaces 33A to 33D demarcate an active mesa 34 at the first main surface 3. The active surface 31 may be referred to as a “first surface,” the outside surface 32 may be referred to as a “second surface” or a “peripheral surface,” and the active mesa 34 may be referred to as a “mesa.”

The active surface 31 is formed at intervals inward from the peripheral edges of the first main surface 3 (first to fourth side surfaces 5A to 5D). The active surface 31 has a flat surface that extends in the first direction X and the second direction Y. The active surface 31 has the off angle θ and the off direction D described above. In this embodiment, the active surface 31 is formed to a quadrilateral shape having four sides parallel to the first to fourth side surfaces 5A to 5D in plan view.

The outside surface 32 is positioned outside the active surface 31 and is recessed in the thickness direction (toward the second main surface 4 side) of the SiC chip 2 from the active surface 31. Specifically, the outside surface 32 is recessed to a depth less than the thickness of the drift region 8 such as to expose the drift region 8. The outside surface 32 is formed as a band that extends along the active surface 31 in plan view. In this embodiment, the outside surface 32 is formed to an annular shape (specifically, a quadrilateral annular shape) that surrounds the active surface 31 in plan view. The outside surface 32 has a flat surface that extends in the first direction X and the second direction Y and is formed substantially parallel to the active surface 31. As with the active surface 31, the outside surface 32 has the off angle θ and the off direction D. The outside surface 32 is in communication with the first to fourth side surfaces 5A to 5D.

The first to fourth connecting surfaces 33A to 33D extend in the normal direction Z and connect the active surface 31 and the outside surface 32. The first connecting surface 33A is positioned at the first side surface 5A side, the second connecting surface 33B is positioned at the second side surface 5B side, the third connecting surface 33C is positioned at the third side surface 5C side, and the fourth connecting surface 33D is positioned at the fourth side surface 5D side. The first connecting surface 33A and the second connecting surface 33B extend in the first direction X and oppose each other in the second direction Y. The third connecting surface 33C and the fourth connecting surface 33D extend in the second direction Y and oppose each other in the first direction X. The first to fourth connecting surfaces 33A to 33D expose the drift region 8.

The first to fourth connecting surfaces 33A to 33D may extend substantially vertically between the active surface 31 and the outside surface 32 such that the active mesa 34 of a quadrilateral prism shape is demarcated. The first to fourth connecting surfaces 33A to 33D may be inclined obliquely downward from the active surface 31 toward the outside surface 32 such that the active mesa 34 of a truncated quadrilateral pyramid shape is demarcated. The SiC semiconductor device 1A thus includes the active mesa 34 that is formed in the drift region 8 at the first main surface 3. The active mesa 34 is formed just in the drift region 8 and is not formed in the base region 6 and the buffer region 7.

The SiC semiconductor device 1A includes the SiC-MISFET that is formed at the active surface 31. The structure of the SiC-MISFET shall now be described specifically. The SiC semiconductor device 1A includes a p-type body region 35 that is formed in a surface layer portion of the active surface 31. The body region 35 forms a portion of a body diode of the SiC-MISFET. The body region 35 may be formed across an entirety of the surface layer portion of the active surface 31.

The SiC semiconductor device 1A includes an n-type source region 36 that is formed in a surface layer portion of the body region 35. The source region 36 forms a source of the SiC-MISFET. The source region 36 may be formed across an entirety of the surface layer portion of the body region 35. The source region 36 has an n-type impurity concentration that exceeds the n-type impurity concentration of the drift region 8. The source region 36 forms SiC-MISFET channels CH with the drift region 8 inside the body region 35.

The SiC semiconductor device 1A includes a plurality of trench gate structures 37 that are formed in the active surface 31. The trench gate structures 37 form a gate of the SiC-MISFET and control inversion (on) and non-inversion (off) of the channels CH. The trench gate structures 37 are formed such as to traverse the body region 35 and the source region 36 and reach the drift region 8.

The trench gate structures 37 are respectively formed as bands that are formed at intervals in the first direction X in plan view and extend in the second direction Y. Each trench gate structure 37 is formed at an interval to the active surface 31 side from the bottom portion of the drift region 8 and opposes the buffer region 7 across a portion of the drift region 8.

Each trench gate structure 37 includes a gate trench 38, a gate insulating film 39, and a gate electrode 40. The gate trench 38 is formed in the active surface 31. The gate insulating film 39 is formed as a film on an inner wall of the gate trench 38. The gate electrode 40 is embedded in the gate trench 38 across the gate insulating film 39. The gate electrode 40 opposes the drift region 8, the body region 35, and the source region 36 across the gate insulating film 39. A gate potential is applied to the gate electrode 40.

The SiC semiconductor device 1A includes a plurality of trench source structures 41 that are formed in the active surface 31. The trench source structures 41 are each formed in a region of the active surface 31 between two adjacent trench gate structures 37. The trench source structures 41 are each formed as a band that extends in the second direction Y in plan view. The trench source structures 41 are formed such as to traverse the body region 35 and the source region 36 and reach the drift region 8. The trench source structures 41 are formed at an interval to the active surface 31 side from the bottom portion of the drift region 8 and oppose the buffer region 7 across a portion of the drift region 8.

Each trench source structure 41 has a depth that exceeds a depth of the trench gate structures 37. A bottom wall of each trench source structure 41 is positioned at a bottom portion side of the drift region 8 with respect to a bottom wall of each trench gate structure 37. In this embodiment, the bottom wall of each trench source structure 41 is positioned on substantially the same plane as the outside surface 32. As a matter of course, each trench source structure 41 may have a depth that is equal to the depth of the trench gate structures 37.

Each trench source structure 41 includes a source trench 42, a source insulating film 43, and a source electrode 44. The source trench 42 is formed in the active surface 31. The source insulating film 43 is formed as a film on an inner wall of the source trench 42. The source electrode 44 is embedded in the source trench 42 across the source insulating film 43. A source potential is applied to the source electrode 44.

The SiC semiconductor device 1A includes a plurality of p-type contact regions 45 that are respectively formed in regions of the drift region 8 that are oriented along the trench source structures 41. A p-type impurity concentration of the contact regions 45 exceeds the p-type impurity concentration of the body region 35. The contact regions 45 each cover a corresponding trench source structure 41 in a multiple-to-one correspondence at intervals in the second direction Y. The contact regions 45 may each cover a corresponding trench source structure 41 in a one-to-one correspondence instead. Each contact region 45 covers a side wall and a bottom wall of each trench source structure 41 and is electrically connected to the body region 35.

The SiC semiconductor device 1A includes a plurality of p-type well regions 46 that are respectively formed in regions of the surface layer portion of the active surface 31 that are oriented along the trench source structures 41. Preferably, a p-type impurity concentration of the well regions 46 exceeds the p-type impurity concentration of the body region 35 but is less than the p-type impurity concentration of the contact regions 45. The well regions 46 each cover a corresponding trench source structure 41 across the contact region 45. Each well region 46 may be formed as a band extending along the corresponding trench source structure 41. Each well region 46 covers the side wall and the bottom wall of each trench source structure 41 and is electrically connected to the body region 35.

Referring to FIG. 34, the SiC semiconductor device 1A includes a p-type outer contact region 48 that is formed in a surface layer portion of the drift region 8 in the outside surface 32. The outer contact region 48 preferably has a p-type impurity concentration that exceeds the p-type impurity concentration of the body region 35. The outer contact region 48 is formed at intervals from peripheral edges of the active surface 31 and peripheral edges of the outside surface 32 in plan view. The outer contact region 48 is formed as a band extending along the active surface 31 in plan view. In this embodiment, the outer contact region 48 is formed to an annular shape (specifically, a quadrilateral annular shape) that surrounds the active surface 31 in plan view.

The outer contact region 48 is formed at an interval to the outside surface 32 from the bottom portion of the drift region 8. The entire outer contact region 48 is positioned at the bottom portion side of the drift region 8 with respect to the bottom walls of the trench gate structures 37. The outer contact region 48 forms a pn-junction portion with the drift region 8. A pn-junction diode having the outer contact region 48 as an anode and the drift region 8 as a cathode is thereby formed.

The SiC semiconductor device 1A includes a p-type outer well region 49 that is formed in a surface layer portion of the outside surface 32. The outer well region 49 has a p-type impurity concentration less than the p-type impurity concentration of the outer contact region 48. The p-type impurity concentration of the outer well region 49 is preferably substantially equal to the p-type impurity concentration of the well regions 46. The outer well region 49 is formed in a region between the peripheral edges of the active surface 31 and the outer contact region 48 in plan view.

The outer well region 49 is formed as a band extending along the active surface 31 in plan view. In this embodiment, the outer well region 49 is formed to an annular shape (specifically, a quadrilateral annular shape) that surrounds the active surface 31 in plan view. The outer well region 49 is electrically connected to the outer contact region 48. In this embodiment, the outer well region 49 extends toward the first to fourth connecting surfaces 33A to 33D from the outside surface 32 and covers the first to fourth connecting surfaces 33A to 33D inside the SiC chip 2. The outer well region 49 is electrically connected to the body region 35 in a surface layer portion of the active surface 31.

The outer well region 49 is formed deeper than the outer contact region 48. The outer well region 49 is formed at an interval to the outside surface 32 from the bottom portion of the drift region 8. The outer well region 49 is positioned at the bottom portion side of the drift region 8 with respect to the bottom walls of the trench gate structures 37. The outer well region 49 forms a pn-junction portion with the drift region 8.

The SiC semiconductor device 1A includes at least one (preferably not less than 2 and not more than 20) p-type field region 50 that is formed in a region of the surface layer portion of the outside surface 32 between the outer contact region 48 and the peripheral edges of the outside surface 32. A plurality of the field regions 50 relax an electric field inside the SiC chip 2 at the outside surface 32. The number, width, depth, p-type impurity concentration, etc., of the field regions 50 are arbitrary and can take on any of various values in accordance with the electric field to be relaxed. In this embodiment, the SiC semiconductor device 1A includes five field regions 50.

The field regions 50 are formed at intervals toward the peripheral edges of the outside surface 32 from the outer contact region 48. The field regions 50 are formed as bands extending along the active surface 31 in plan view. In this embodiment, the field regions 50 are formed to annular shapes (specifically, quadrilateral annular shapes) that surround the active surface 31 in plan view. Thereby, the field regions 50 are each formed as an FLR (field limiting ring).

The field regions 50 are formed at intervals to the outside surface 32 from the bottom portion of the drift region 8. The field regions 50 are positioned at the bottom portion side of the drift region 8 with respect to the bottom walls of the trench gate structures 37. The field regions 50 are formed deeper than the outer contact region 48. The innermost field region 50 may be connected to the outer contact region 48. The field regions 50 other than the innermost field region 50 may be formed in an electrically floating state.

The SiC semiconductor device 1A includes a main surface insulating film 51 that covers the first main surface 3 (active surface 31, outside surface 32, and first to fourth connecting surfaces 33A to 33D). The main surface insulating film 51 is continuous to the gate insulating film 39 and the source insulating film 43 and exposes the gate electrode 40 and the source electrode 44.

The SiC semiconductor device 1A includes a side wall structure 52 that is formed above the outside surface 32 such as to cover at least one among the first to fourth connecting surfaces 33A to 33D. Specifically, the side wall structure 52 is formed on the main surface insulating film 51. The side wall structure 52 may include an inorganic insulator or polysilicon.

The SiC semiconductor device 1A includes an interlayer insulating film 53 that is formed on the main surface insulating film 51. The interlayer insulating film 53 covers the active surface 31, the outside surface 32, and the first to fourth connecting surfaces 33A to 33D. The interlayer insulating film 53 covers the main surface insulating film 51 across the side wall structure 52.

The SiC semiconductor device 1A includes a gate main surface electrode 54 (first main surface electrode) that is formed on the first main surface 3 (is formed on the interlayer insulating film 53). The gate main surface electrode 54 transmits the gate potential that is input from the exterior to the trench gate structures 37 (gate electrodes 40). In this embodiment, the gate main surface electrode 54 is arranged on the active surface 31 but is not arranged on the outside surface 32. The gate main surface electrode 54 includes a gate pad electrode 55 and a gate wiring electrode 56. In this embodiment, the gate pad electrode 55 is arranged in a region of a peripheral edge portion of the active surface 31 that is adjacent to a central portion of the first connecting surface 33A.

The gate wiring electrode 56 is led out onto the interlayer insulating film 53 from the gate main surface electrode 54. The gate wiring electrode 56 is formed as a band that extends along the peripheral edges of the active surface 31 such as to intersect (specifically, to be orthogonal to) end portions of the trench gate structures 37 in plan view. The gate wiring electrode 56 penetrates through the interlayer insulating film 53 and is electrically connected to the trench gate structures 37 (gate electrodes 40). The gate wiring electrode 56 transmits the gate potential applied to the gate main surface electrode 54 to the trench gate structures 37.

The SiC semiconductor device 1A includes a source main surface electrode 57 (second main surface electrode) that is formed on the first main surface 3 (is formed on the interlayer insulating film 53). The source main surface electrode 57 transmits the source potential that is input from the exterior to the trench source structures 41 (source electrodes 44). In this embodiment, the source main surface electrode 57 is arranged on the active surface 31 and the outside surface 32. The source main surface electrode 57 includes a source pad electrode 58 and a source wiring electrode 59. The source pad electrode 58 is arranged on the active surface 31 at an interval from the gate main surface electrode 54.

In this embodiment, the source pad electrode 58 is formed to a polygonal shape having a recess portion that is recessed toward an inside of the active surface 31 such as to conform to the gate main surface electrode 54 at sides along the gate main surface electrode 54 in plan view. The source pad electrode 58 penetrates through the interlayer insulating film 53 and is electrically connected to the trench source structures 41, the source region 36, and the well regions 46. The source pad electrode 58 transmits the source potential input from the exterior to the trench source structures 41, the source region 36, and the well regions 46.

The source wiring electrode 59 is formed as a band that is led out onto the interlayer insulating film 53 from the source pad electrode 58 and extends along the peripheral edges of the active surface 31 (first to fourth connecting surfaces 33A to 33D). In this embodiment, the source wiring electrode 59 is formed to an annular shape (specifically, a quadrilateral annular shape) that surrounds the gate main surface electrode 54, the source pad electrode 58, and the gate wiring electrode 56 altogether in plan view.

The source wiring electrode 59 covers the side wall structure 52 across the interlayer insulating film 53 and is led out from the active surface 31 side to the outside surface 32 side. At the outside surface 32 side, the source wiring electrode 59 penetrates through the interlayer insulating film 53 and is electrically connected to the outer contact region 48. Preferably, along its entire periphery, the source wiring electrode 59 covers an entirety of the side wall structure 52 and an entirety of the outer contact region 48. The source wiring electrode 59 transmits the source potential applied to the source pad electrode 58 to the outer contact regions 48.

The SiC semiconductor device 1A includes a drain electrode 60 (third main surface electrode) that is formed on the second main surface 4. The drain electrode 60 covers the entirety of the second main surface 4 and is continuous to peripheral edges of the second main surface 4 (first to fourth side surfaces 5A to 5D). The drain electrode 60 forms an ohmic contact with the base region 6 (second main surface 4). The drain electrode 60 transmits a drain potential to the base region 6.

With the structure described above, the SiC semiconductor device 1A having the trench gate type SiC-MISFET that is improved in electrical characteristics by the drift region 8 can be provided. As a matter of course, the structure of the functional device 9 (SiC-MISFET) according to the third configuration example can be applied to any one of the first to twelfth preferred embodiments other than the first preferred embodiment as well.

For example, if the structure of the functional device 9 according to the third configuration example is to be applied to the drift region 8 that has the first region 8a and the second region 8b, the active mesa 34 is formed just in the second region 8b of the drift region 8 and the functional device 9 is formed in the second region 8b. Also, if the structure of the functional device 9 according to the third configuration example is to be formed in the p-type drift region 18, the structure would be one in which the “n-type regions” are replaced by “p-type regions” and the “p-type regions” are replaced by “n-type regions.”

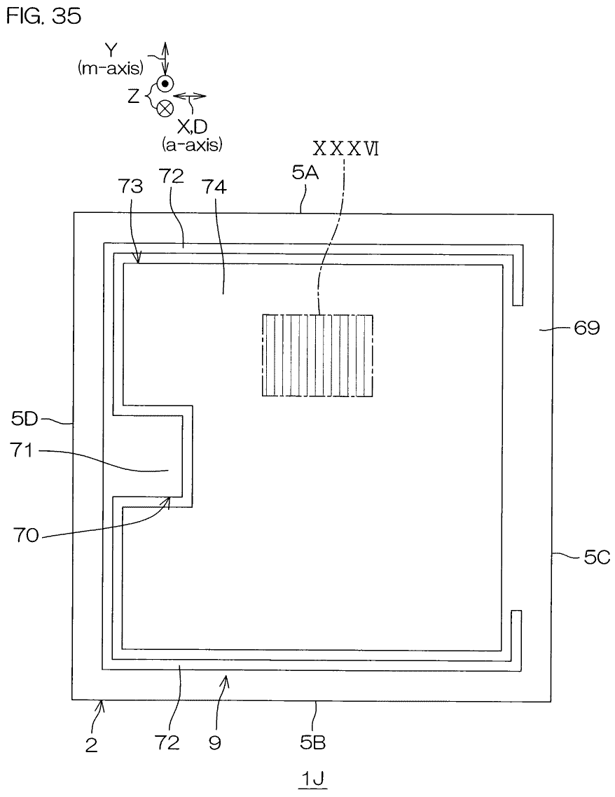

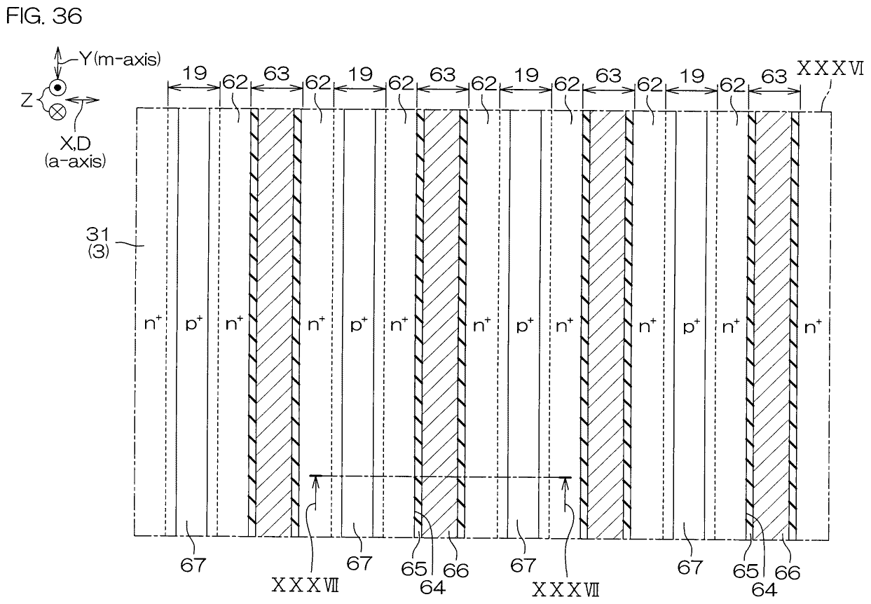

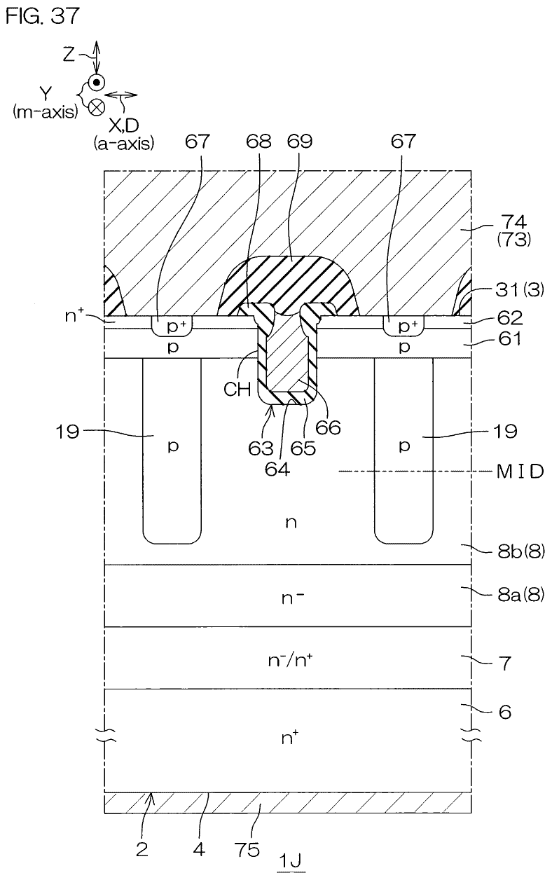

FIG. 35 is a plan view of a structure with which the functional device 9 according to a fourth configuration example is applied to the SiC semiconductor device 1J according to the tenth preferred embodiment. FIG. 36 is an enlarged view of a region XXXVI shown in FIG. 35. FIG. 37 is a sectional view taken along line XXXVII-XXXVII shown in FIG. 36. In the following, structures corresponding to structures described with the tenth preferred embodiment shall be provided with the same reference signs and description thereof shall be omitted.

Referring to FIG. 35 to FIG. 37, the SiC semiconductor device 1J includes the SiC chip 2, the n-type base region 6, the n-type buffer region 7, the n-type drift region 8, the p-type column regions 19, and the functional device 9. As in the case of the tenth preferred embodiment, the drift region 8 includes the first region 8a and the second region 8b. As in the case of the tenth preferred embodiment, the column regions 19 are formed in the second region 8b. In FIG. 35 to FIG. 37, an example where, in plan view, the column regions 19 are formed as bands that are aligned at intervals in the first direction X (a-axis direction) and extend in the second direction Y (m-axis direction) is shown. In this embodiment, the functional device 9 is a trench gate/super junction type SiC-MISFET. The structure of the SIC-MISFET shall now be described specifically.

The SiC semiconductor device 1J includes a p-type body region 61 that is formed in a surface layer portion of the first main surface 3. The body region 61 forms a portion of a body diode of the SiC-MISFET. Specifically, the body region 61 is formed at an interval to the first main surface 3 side from the lower end portions of the column regions 19 such as to be connected to the column regions 19. The body region 61 is preferably formed at an interval to the first main surface 3 side from the intermediate portions of the column regions 19.

The SiC semiconductor device 1J includes an n-type source region 62 that is formed in a surface layer portion of the body region 61. The source region 62 forms a source of the SiC-MISFET. The source region 62 has an n-type impurity concentration that exceeds the n-type impurity concentration of the drift region 8. The source region 62 forms SiC-MISFET channels CH with the drift region 8 inside the body region 61.

The SiC semiconductor device 1J includes a plurality of trench gate structures 63 that are formed in the first main surface 3. The trench gate structures 63 form a gate of the SiC-MISFET and control inversion (on) and non-inversion (off) of the channels CH. The trench gate structures 63 are formed such as to traverse the body region 61 and the source region 62 and reach the drift region 8.

Specifically, the trench gate structures 63 are each formed in a region between two adjacent column regions 19 in plan view. The trench gate structures 63 are each formed as a band that extends in the direction in which the column regions 19 extend in plan view. That is, the trench gate structures 63 are aligned as stripes that extend in parallel to the column regions 19. As a matter of course, the trench gate structures 63 are each formed as a band that extends in a direction intersecting (orthogonal to) the column regions 19 in plan view.

Each trench gate structure 63 is formed at an interval to the first main surface 3 side from the bottom portion of the drift region 8 and opposes the buffer region 7 across a portion of the drift region 8. Specifically, each trench gate structure 63 is formed inside the second region 8b at an interval to the first main surface 3 side from the first region 8a and opposes the buffer region 7 across a portion of the second region 8b and the first region 8a.

Each trench gate structure 63 includes a gate trench 64, a gate insulating film 65, and a gate electrode 66. The gate trench 64 is formed in the first main surface 3. The gate insulating film 65 is formed as a film on an inner wall of the gate trench 64. The gate electrode 66 is embedded in the gate trench 64 across the gate insulating film 65. The gate electrode 66 opposes the drift region 8 (second region 8b), the body region 61, and the source region 62 across the gate insulating film 65. A gate potential is applied to the gate electrode 66.

The SiC semiconductor device 1J includes a plurality of p-type contact regions 67 that are formed in a surface layer portion of the body region 61. A p-type impurity concentration of the contact regions 67 exceeds the p-type impurity concentration of the body region 61. The contact regions 67 are each formed in a region between two adjacent gate trenches 64 in plan view. The contact regions 67 respectively oppose the column regions 19 in a one-to-one correspondence in plan view. The contact regions 67 are each formed as a band that extends in the second direction Y in plan view. The contact regions 67 are each formed at intervals in the first direction X from two adjacent gate trenches 64.

The SiC semiconductor device 1J includes a main surface insulating film 68 that covers the first main surface 3. The main surface insulating film 68 is continuous to the gate insulating film 65 and exposes the gate electrode 66. The SiC semiconductor device 1J includes an interlayer insulating film 69 that is formed on the main surface insulating film 68. The interlayer insulating film 69 covers the first main surface 3 across the main surface insulating film 68.

The SiC semiconductor device 1J includes a gate main surface electrode 70 (first main surface 3 electrode) that is formed on the first main surface 3 (is formed on the interlayer insulating film 69). The gate main surface electrode 70 transmits the gate potential that is input from the exterior to the trench gate structures 63 (gate electrodes 66). The gate main surface electrode 70 includes a gate pad electrode 71 and a gate wiring electrode 72. In this embodiment, the gate pad electrode 71 is arranged in a region of a peripheral edge portion of the first main surface 3 that is adjacent to a central portion of the first side surface 5A.

The gate wiring electrode 72 is led out onto the interlayer insulating film 69 from the gate main surface electrode 70. The gate wiring electrode 72 is formed as a band that extends along the peripheral edges of the first main surface 3 such as to intersect (specifically, to be orthogonal to) end portions of the trench gate structures 63 in plan view. The gate wiring electrode 72 penetrates through the interlayer insulating film 69 and is electrically connected to the trench gate structures 63 (gate electrodes 66). The gate wiring electrode 72 transmits the gate potential applied to the gate main surface electrode 70 to the trench gate structures 63.

The SiC semiconductor device 1J includes a source main surface electrode 73 (second main surface electrode) that is formed on the first main surface 3 (is formed on the interlayer insulating film 69). The source main surface electrode 73 transmits the source potential that is input from the exterior to the source region 62 and the contact regions 67. The source main surface electrode 73 includes a source pad electrode 74. The source pad electrode 74 is arranged on the first main surface 3 at an interval from the gate main surface electrode 70.

In this embodiment, the source pad electrode 74 is formed to a polygonal shape having a recess portion that is recessed toward an inside of the first main surface 3 such as to conform to the gate main surface electrode 70 at sides along the gate main surface electrode 70 in plan view. The source pad electrode 74 penetrates through the interlayer insulating film 69 and is electrically connected to the source region 62 and the contact regions 45. The source pad electrode 74 transmits the source potential input from the exterior to the source region 62 and the contact regions 45.

The SiC semiconductor device 1J includes a drain electrode 75 (third main surface electrode) that is formed on the second main surface 4. The drain electrode 75 covers the entirety of the second main surface 4 and is continuous to peripheral edges of the second main surface 4 (first to fourth side surfaces 5A to 5D). The drain electrode 75 forms an ohmic contact with the base region 6 (second main surface 4).

With the structure described above, the SiC semiconductor device 1J having the trench gate/super junction type SiC-MISFET that is improved in electrical characteristics by the drift region 8 and the column regions 19 can be provided. As a matter of course, the structure of the functional device 9 (SiC-MISFET) according to the fourth configuration example can be applied to any one of the ninth to twelfth preferred embodiments other than the tenth preferred embodiment as well. For example, if the structure of the functional device 9 according to the fourth configuration example is to be formed in the p-type drift region 18, the structure would be one in which the “n-type regions” are replaced by “p-type regions” and the “p-type regions” are replaced by “n-type regions.”

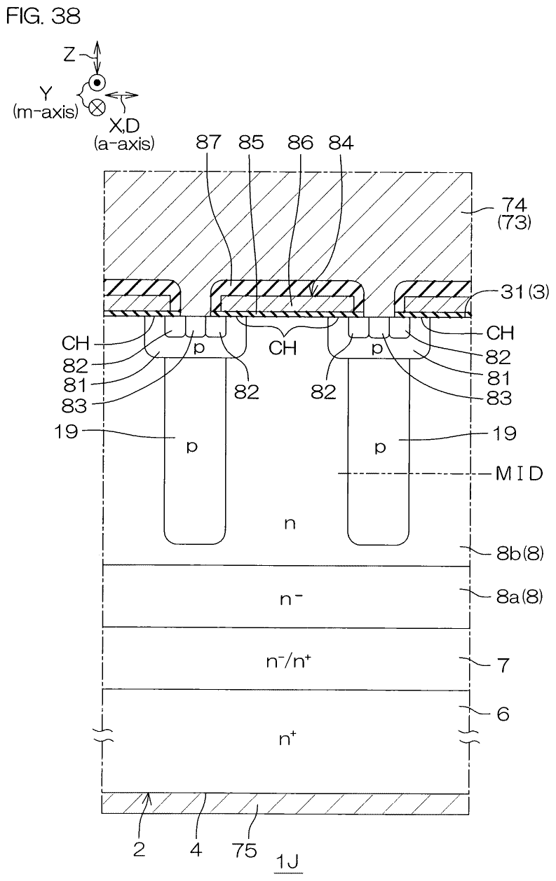

FIG. 38 is a sectional view of a structure with which the functional device 9 according to a fifth configuration example is applied to the SiC semiconductor device 1J according to the tenth preferred embodiment. In the following, structures corresponding to structures described with the tenth preferred embodiment shall be provided with the same reference signs and description thereof shall be omitted.

Referring to FIG. 38, the SiC semiconductor device 1J includes the SiC chip 2, the n-type base region 6, the n-type buffer region 7, the n-type drift region 8, the p-type column regions 19, and the functional device 9. As in the case of the tenth preferred embodiment, the drift region 8 includes the first region 8a and the second region 8b. As in the case of the tenth preferred embodiment, the column regions 19 are formed in the second region 8b. In FIG. 38, an example where, in plan view, the column regions 19 are formed as bands that are aligned at intervals in the first direction X (a-axis direction) and extend in the second direction Y (m-axis direction) is shown. In this embodiment, the functional device 9 is a planar gate/super junction type SiC-MISFET. The structure of the SIC-MISFET shall now be described specifically.

The SiC semiconductor device 1J includes a plurality of p-type body regions 81 that are formed in a surface layer portion of the first main surface 3. The body regions 81 form a portion of a body diode of the SiC-MISFET. Specifically, the body regions 81 are formed at intervals to the first main surface 3 side from the lower end portions of the column regions 19 such as to be connected to the column regions 19 in a one-to-one correspondence. In regard to the thickness direction, the body regions 81 are preferably formed at intervals to the first main surface 3 side from the intermediate portions of the column regions 19. The body regions 81 may respectively be formed as bands that extend along the column regions 19 in plan view.

The SiC semiconductor device 1J includes a plurality of n-type source regions 82 that are respectively formed in surface layer portions of the body regions 81. Form a source of the SiC-MISFET. The source regions 82 have an n-type impurity concentration that exceeds the n-type impurity concentration of the drift region 8. The source regions 82 are each formed in an inner portion of the corresponding body region 81 at intervals from peripheral edges of the corresponding body region 81 in plan view. The source regions 82 may respectively be formed as bands that extend along the column regions 19 in plan view. The source regions 82 form SiC-MISFET channels CH with the drift region 8 inside the body regions 81.

The SiC semiconductor device 1J includes a plurality of p-type contact regions 83 that are respectively formed in surface layer portions of the body regions 81. A p-type impurity concentration of the contact regions 83 exceeds the p-type impurity concentration of the body regions 81. The contact regions 83 are each formed in the surface layer portion of the corresponding body region 81 such as to penetrate through the corresponding source region 82. The contact regions 83 may respectively be formed as bands that extend along the column region 19 in plan view

The SiC semiconductor device 1J includes a plurality of planar gate structures 84 that are formed on the first main surface 3. The planar gate structures 84 form a gate of the SiC-MISFET and control inversion (on) and non-inversion (off) of the channels CH. The planar gate structures 84 respectively cover the drift region 8, the body regions 81, and the source regions 82.

Specifically, the planar gate structures 84 are each formed in a region between two adjacent body regions 81 in plan view. The planar gate structures 84 are each formed as a band that extends in the direction in which the column regions 19 extend in plan view. That is, the planar gate structures 84 are aligned as stripes that extend in parallel to the column regions 19. As a matter of course, the planar gate structures 84 are each formed as a band that extends in a direction intersecting (orthogonal to) the column regions 19 in plan view.

Each planar gate structure 84 includes a gate insulating film 85 and a gate electrode 86. On the first main surface 3, the gate insulating films 85 cover the channel CH. Specifically, the gate insulating films 85 cover the drift region 8 (second region 8b), the body regions 81, and the source regions 82. The gate electrodes 86 oppose the channels CH across the gate insulating films 85. Specifically, the gate electrodes 86 oppose the drift region 8 (second region 8b), the body regions 81, and the source regions 82 across the gate insulating films 85. A gate potential is applied to the gate electrodes 86.

The SiC semiconductor device 1J includes an interlayer insulating film 87 that is formed on the first main surface 3. The interlayer insulating film 87 covers the planar gate structures 84. As with the functional device 9 according to the third configuration example, the SiC semiconductor device 1J includes the gate main surface electrode 70 (first main surface electrode), the source main surface electrode 73 (second main surface electrode), and the drain electrode 75 (third main surface electrode). The gate main surface electrode 70 includes the gate pad electrode 71 and the gate wiring electrode 72. The gate wiring electrode 72 penetrates through the interlayer insulating film 87 and is electrically connected to the planar gate structures 84 (gate electrodes 86). The source main surface electrode 73 includes the source pad electrode 74. The source pad electrode 74 penetrates through the interlayer insulating film 87 and is electrically connected to the source regions 82 and the contact regions 45.

With the structure described above, the SiC semiconductor device 1J having the planar gate/super junction type SiC-MISFET that is improved in electrical characteristics by the drift region 8 and the column regions 19 can be provided. As a matter of course, the structure of the functional device 9 (SiC-MISFET) according to the fifth configuration example can be applied to any one of the ninth to twelfth preferred embodiments other than the tenth preferred embodiment as well. For example, if the structure of the functional device 9 according to the fifth configuration example is to be formed in the p-type drift region 18, the structure would be one in which the “n-type regions” are replaced by “p-type regions” and the “p-type regions” are replaced by “n-type regions.”

The preferred embodiments of the present invention described above may be implemented in yet other embodiments. With each of the preferred embodiments described above, the structure with which the first direction X is the a-axis direction ([11-20] direction) of the SiC monocrystal and the second direction Y is the m-axis direction ([1-100] direction) of the SiC monocrystal was described. However, with each of the preferred embodiments described above, a structure with which the first direction X is the m-axis direction ([1-100] direction) of the SiC monocrystal and the second direction Y is the a-axis direction ([11-20] direction) of the SiC monocrystal may be adopted instead. A specific structure in such a case is obtained by interchanging the “a-axis direction” and the “m-axis direction” in each of the preferred embodiments described above.

With each of the preferred embodiments described above, an example where the SiC chip 2 is adopted was described. However, in place of the SiC chip 2, a WBG (wide band gap) semiconductor chip constituted of a WBG semiconductor other than SiC may be adopted instead. A WBG semiconductor is a semiconductor having a band gap that exceeds a band gap of Si (silicon). A specific structure in this case is obtained by replacing “SiC” by “WBG semiconductor” in the description of each of the preferred embodiments described above. A WBG semiconductor chip may, for example, be constituted of a diamond chip that is constituted of a C monocrystal (diamond). That is, the WBG semiconductor chip may be constituted of a WBG semiconductor monocrystal that includes C (carbon).

With each of the ninth and tenth preferred embodiments described above, an example where the drift region 8 has an impurity concentration that is adjusted by at least two types of pentavalent elements and the column regions 19 have an impurity concentration that is adjusted by a trivalent element other than boron was described. However, in each of the ninth and tenth preferred embodiments described above, it is possible for the drift region 8 to have an impurity concentration that is adjusted by at least two types of pentavalent elements and the column regions 19 to have an impurity concentration that is adjusted by any trivalent element instead. Also, in each of the ninth and tenth preferred embodiments described above, it is possible for the drift region 8 to have an impurity concentration that is adjusted by any pentavalent element and the column regions 19 to have an impurity concentration that is adjusted by a trivalent element other than boron instead.

With each of the eleventh and twelfth preferred embodiments described above, an example where the drift region 18 has an impurity concentration that is adjusted by a trivalent element other than boron and the column regions 20 have an impurity concentration that is adjusted by a pentavalent element other than phosphorus and nitrogen was described. However, in each of the eleventh and twelfth preferred embodiments described above, it is possible for the drift region 18 to have an impurity concentration that is adjusted by a trivalent element other than boron and the column regions 20 to have an impurity concentration that is adjusted by any pentavalent element instead. Also, in each of the eleventh and twelfth preferred embodiments described above, it is possible for the drift region 18 to have an impurity concentration that is adjusted by any pentavalent element and the column regions 20 to have an impurity concentration that is adjusted by a pentavalent element other than phosphorus and nitrogen instead.

Examples of features extracted from the present description and drawings are indicated below. Each of [A1] to [A29], [B1] to [B22], [C1] to [C33], and [D1] to [D24] indicated below provides a semiconductor device that can be improved in electrical characteristics. Each of [E1] to [E22] indicated below provides a method for manufacturing a semiconductor device that can be improved in electrical characteristics. Although alphanumeric characters within parenthesis in the following express corresponding constituent elements, etc., in the preferred embodiments described above, these are not meant to limit the scopes of the respective items to the preferred embodiments.

[A1] A semiconductor device (1A to 1L) comprising: a WBG (wide band gap) semiconductor chip (2) that has a main surface (3); and an n-type drift region (8, 18) that is formed in a surface layer portion of the main surface (3) and has an impurity concentration adjusted by at least two types of pentavalent elements.

[A2] The semiconductor device (1A to 1L) according to A1, wherein the drift region (8, 18) has an impurity concentration that is adjusted such as to increase toward the main surface (3).

[A3] The semiconductor device (1A to 1L) according to A1 or A2, wherein the drift region (8, 18) has an impurity concentration adjusted by pentavalent elements other than phosphorus.

[A4] The semiconductor device (1A to 1L) according to any one of A1 to A3, wherein the drift region (8, 18) includes nitrogen as a pentavalent element and a pentavalent element other than nitrogen.

[A5] The semiconductor device (1A to 1L) according to any one of A1 to A4, wherein the drift region (8, 18) has a basal concentration (CA) due to a first impurity that is a pentavalent element and an added concentration (CB) due to a second impurity that is a pentavalent element other than the first impurity.

[A6] The semiconductor device (1A to 1L) according to A5, wherein the first impurity is a pentavalent element other than phosphorus, and the second impurity is a pentavalent element other than phosphorus.

[A7] The semiconductor device (1A to 1L) according to A6, wherein the first impurity is nitrogen, and the second impurity is at least one among arsenic and antimony.

[A8] The semiconductor device (1A to 1L) according to any one of A5 to A7, wherein the added concentration (CB) has a concentration distribution that increases toward the main surface (3).

[A9] The semiconductor device (1A to 1L) according to any one of A5 to A8, wherein the basal concentration (CA) has a concentration distribution that is substantially constant in a thickness direction.

[A10] A semiconductor device (1A to 1L) comprising: a WBG (wide band gap) semiconductor chip (2) that has a main surface (3); and a p-type drift region (8, 18) that is formed in a surface layer portion of the main surface (3) and has an impurity concentration adjusted by a trivalent element other than boron.

[A11] The semiconductor device (1A to 1L) according to A10, wherein the drift region (8, 18) has an impurity concentration that is adjusted such as to increase toward the main surface (3).

[A12] The semiconductor device (1A to 1L) according to A10 or A11, wherein the drift region (8, 18) includes at least one type of trivalent element among aluminum, gallium, and indium.

[A13] The semiconductor device (1A to 1L) according to any one of A10 to A12, wherein the drift region (8, 18) has a basal concentration (CA) due to a first impurity that is a trivalent element and an added concentration (CB) due to a second impurity that is a trivalent element being the same as or different from the first impurity.

[A14] The semiconductor device (1A to 1L) according to A13, wherein the first impurity is aluminum, and the second impurity is at least one among aluminum, gallium, and indium.

[A15] The semiconductor device (1A to 1L) according to A13 or A14, wherein the added concentration (CB) has a concentration distribution that increases toward the main surface (3).

[A16] The semiconductor device (1A to 1L) according to any one of A13 to A15, wherein the basal concentration (CA) has a concentration distribution that is substantially constant in a thickness direction.

[A17] The semiconductor device (1A to 1L) according to any one of A1 to A16, wherein the drift region (8, 18) has a thickness belonging to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

[A18] The semiconductor device (1A to 1L) according to any one of A1 to A17, wherein the WBG semiconductor chip (2) includes C (carbon).

[A19] The semiconductor device (1A to 1L) according to any one of A1 to A18, wherein the WBG semiconductor chip (2) is constituted of an SiC chip (2).

[A20] The semiconductor device (1A to 1L) according to A19, wherein the SiC chip (2) is constituted of an SiC monocrystal that is a hexagonal crystal, and the main surface (3) is arranged along a c-plane of the SiC monocrystal and has an off angle (θ) of not more than 10° with respect to the c-plane.

[A21] The semiconductor device (1A to 1L) according to A20, wherein the off angle (θ) has an off direction (D) oriented along an a-axis direction of the SiC monocrystal.

[A22] The semiconductor device (1A to 1L) according to any one of A1 to A21, wherein the drift region (8, 18) is formed in a WBG semiconductor epitaxial layer.

[A23] The semiconductor device (1A to 1L) according to any one of A1 to A22, further comprising: a functional device (9) that is formed in the main surface (3).

[A24] The semiconductor device (1A to 1L) according to A23, wherein the functional device (9) includes a diode.

[A25] The semiconductor device (1A to 1L) according to A24, further comprising: an insulating film (22) that covers the main surface (3) such as to partially expose the main surface (3); a first main surface electrode (23) that is electrically connected to the main surface (3); and a second main surface electrode (24) that is formed on a surface (4) at an opposite side to the main surface (3).

[A26] The semiconductor device (1A to 1L) according to A25, wherein the insulating film (22) exposes the drift region (8, 18), and the first main surface electrode (23) forms a Schottky junction with the drift region (8, 18).

[A27] The semiconductor device (1A to 1L) according to A23, wherein the functional device (9) further includes a transistor.

[A28] The semiconductor device (1A to 1L) according to A27, further comprising: a channel (CH) that is formed in a surface layer portion of the drift region (8, 18); and a gate structure (37, 63, 84) that is formed in the main surface (3) and controls on/off of the channel (CH).

[A29] The semiconductor device (1A to 1L) according to A28, further comprising: a first main surface electrode (54, 70) that is arranged on the main surface (3) and is electrically connected to the gate structure (37, 63, 84); a second main surface electrode (57, 73) that is arranged on the main surface (3) and is electrically connected to the channel (CH); and a third main surface electrode (60, 75) that is formed on a surface (4) at an opposite side to the main surface (3).

[B1] A semiconductor device (1A to 1L) comprsing: a WBG (wide band gap) semiconductor chip (2) that has a first main surface (3) at one side and a second main surface (4) at another side; a base region (6, 16) of a first conductivity type that is formed in a region inside the WBG semiconductor chip (2) at the second main surface (4) side, includes a first impurity of the first conductivity type, and has a first concentration (C1); a buffer region (7, 17) of the first conductivity type that is formed in a region inside the WBG semiconductor chip (2) at the first main surface (3) side with respect to the base region (6, 16), includes the first impurity, and has a concentration distribution that decreases from the first concentration (C1) to a second concentration (C2) with the base region (6, 16) as a starting point; and a drift region (8, 18) of the first conductivity type that is formed in a region inside the WBG semiconductor chip (2) between the first main surface (3) and the buffer region (7, 17), includes the first impurity and a second impurity of the first conductivity type that differs from the first impurity, and has a concentration distribution that increases from the second concentration (C2) to a third concentration (C3) with the buffer region (7, 17) as a starting point.

[B2] The semiconductor device (1A to 1L) according to B1, wherein the drift region (8, 18) includes the first impurity and the second impurity in a region at a surface layer portion side and a region at a bottom portion side with respect to an intermediate portion (MID) between the first main surface (3) and the buffer region (7, 17).

[B3] The semiconductor device (1A to 1L) according to B1 or B2, wherein the third concentration (C3) is less than the first concentration (C1).

[B4] The semiconductor device (1A to 1L) according to any one of B1 to B3, wherein the third concentration (C3) is not less than 10 times the second concentration (C2).

[B5] The semiconductor device (1A to 1L) according to any one of B1 to B4, wherein the drift region (8, 18) includes a basal concentration (CA) due to the first impurity and an added concentration (CB) due to the second impurity.

[B6] The semiconductor device (1A to 1L) according to B5, wherein the added concentration (CB) has a concentration distribution that increases toward the first main surface (3).

[B7] The semiconductor device (1A to 1L) according to B5 or B6, wherein the basal concentration (CA) has a concentration distribution that is substantially constant in a thickness direction.

[B8] The semiconductor device (1A to 1L) according to any one of B1 to B7, wherein the first conductivity type is an n-type.

[B9] The semiconductor device (1A to 1L) according to B8, wherein the first impurity is a pentavalent element other than phosphorus.

[B10] The semiconductor device (1A to 1L) according to B8 or B9, wherein the first impurity is nitrogen.

[B1l] The semiconductor device (1A to 1L) according to any one of B8 to B10, wherein the second impurity is a pentavalent element other than phosphorus.

[B12] The semiconductor device (1A to 1L) according to any one of B8 to B11, wherein the second impurity is at least one among arsenic and antimony.

[B13] The semiconductor device (1A to 1L) according to any one of B1 to B12, wherein the base region (6, 16) has a first thickness, the buffer region (7, 17) has a second thickness that is less than the first thickness, and the drift region (8, 18) has a third thickness that is not less than the second thickness.

[B14] The semiconductor device (1A to 1L) according to B13, wherein the third thickness is less than the first thickness.

[B15] The semiconductor device (1A to 1L) according to B13 or B14, wherein the third thickness belongs to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

[B16] The semiconductor device (1A to 1L) according to any one of B1 to B15, wherein the WBG semiconductor chip (2) includes carbon (C).

[B17] The semiconductor device (1A to 1L) according to any one of B1 to B16, wherein the WBG semiconductor chip (2) is constituted of an SiC chip (2).

[B18] The semiconductor device (1A to 1L) according to B17, wherein the SiC chip (2) is constituted of an SiC monocrystal that is a hexagonal crystal, and the first main surface (3) is arranged along a c-plane of the SiC monocrystal and has an off angle (θ) of not more than 10° with respect to the c-plane.

[B19] The semiconductor device (1A to 1L) according to B18, wherein the off angle (θ) has an off direction (D) oriented along an a-axis direction of the SiC monocrystal.

[B20] The semiconductor device (1A to 1L) according to any one of B1 to B19, wherein the base region (6, 16) is formed in a semiconductor substrate, the buffer region (7, 17) is formed in an epitaxial layer, and the drift region (8, 18) is formed in an epitaxial layer.

[B21] The semiconductor device (1A to 1L) according to any one of B1 to B20, further comprising: a functional device (9) that is formed in the first main surface (3).

[B22] The semiconductor device (1A to 1L) according to B21, wherein the functional device (9) includes at least one among a diode and a transistor.

[C1] A semiconductor device (1A to 1L) comprising: a WBG (wide band gap) semiconductor chip (2) that has a main surface (3); an n-type drift region (8, 18) that is formed in a surface layer portion of the main surface (3) and has an impurity concentration adjusted by at least two types of pentavalent elements; and a p-type impurity region (19, 20) that is formed inside the drift region (8, 18) such as to form a pn-junction portion with the drift region (8, 18).

[C2] A semiconductor device (1A to 1L) comprising: a WBG semiconductor chip (2) that has a main surface (3); an n-type drift region (8, 18) that is formed in a surface layer portion of the main surface (3); and a p-type impurity region (19, 20) that is formed inside the drift region (8, 18) such as to form a pn-junction portion with the drift region (8, 18) and has an impurity concentration adjusted by a trivalent element other than boron.

[C3] The semiconductor device (1A to 1L) according to C2, wherein the drift region (8, 18) has an impurity concentration adjusted by at least two types of pentavalent elements.

[C4] The semiconductor device (1A to 1L) according to any one of C1 to C3, wherein the drift region (8, 18) has a concentration distribution that increases toward the main surface (3), and the impurity region (19, 20) has a concentration distribution that increases toward the main surface (3).

[C5] The semiconductor device (1A to 1L) according to any one of C1 to C4, wherein the drift region (8, 18) includes a pentavalent element other phosphorus.

[C6] The semiconductor device (1A to 1L) according to any one of C1 to C5, wherein the impurity region (19, 20) includes at least one type of trivalent element among aluminum, gallium, and indium.

[C7] The semiconductor device (1A to 1L) according to any one of C1 to C6, wherein the impurity region (19, 20) extends in a thickness direction inside the drift region (8, 18) such as to form a super junction structure by the pn-junction portion with the drift region (8, 18).

[C8] The semiconductor device (1A to 1L) according to any one of C1 to C7, wherein the impurity region (19, 20) traverses an intermediate portion (MID) of the drift region (8, 18) in regard to a thickness direction of the drift region (8, 18).

[C9] The semiconductor device (1A to 1L) according to any one of C1 to C8, wherein the impurity region (19, 20) is formed at an interval to the main surface (3) side from a bottom portion of the drift region (8, 18).

[C10] The semiconductor device (1A to 1L) according to any one of C1 to C9, wherein the drift region (8, 18) includes a basal concentration (CA) due to a first impurity that is a pentavalent element and an added concentration (CB) due to a second impurity that is a pentavalent element other than the first impurity.

[C11] The semiconductor device (1A to 1L) according to C10, wherein the drift region (8, 18) includes a first region (8a, 18a) that is formed separated from the main surface (3) in a surface layer portion of the main surface (3) and is constituted of the basal concentration (CA) and a second region (8b, 18b) that is formed in a region between the main surface (3) and the first region (8a, 18a) and is constituted of the basal concentration (CA) and the added concentration (CB), and the impurity region (19, 20) is formed inside the second region (8b, 18b) such as to form the pn-junction portion with the second region (8b, 18b).

[C12] The semiconductor device (1A to 1L) according to C11, wherein the impurity region (19, 20) is formed inside the second region (8b, 18b) at an interval to the main surface (3) side from the first region (8a, 18a).

[C13] The semiconductor device (1A to 1L) according to any one of C10 to C12, wherein the added concentration (CB) has a concentration distribution that increases toward the main surface (3).

[C14] The semiconductor device (1A to 1L) according to any one of C10 to C13, wherein the basal concentration (CA) has a concentration distribution that is substantially constant in a thickness direction.

[C15] The semiconductor device (1A to 1L) according to any one of C10 to C14, wherein the first impurity is a pentavalent element other than phosphorus.

[C16] The semiconductor device (1A to 1L) according to any one of C10 to C15, wherein the first impurity is nitrogen, and the second impurity is at least one among arsenic and antimony.

[C17] A semiconductor device (1A to 1L) comprising: a WBG semiconductor chip (2) that has a main surface (3); a p-type drift region (8, 18) that is formed in a surface layer portion of the main surface (3) and has an impurity concentration adjusted by a trivalent element other than boron; and an n-type impurity region (19, 20) that is formed inside the drift region (8, 18) such as to form a pn-junction portion with the drift region (8, 18) and has an impurity concentration that is adjusted by a pentavalent element other than phosphorus and nitrogen.

[C18] The semiconductor device (1A to 1L) according to C17, wherein the drift region (8, 18) has a concentration distribution that increases toward the main surface (3), and the impurity region (19, 20) has a concentration distribution that increases toward the main surface (3).

[C19] The semiconductor device (1A to 1L) according to C17 or C18, wherein the impurity region (19, 20) extends in a thickness direction inside the drift region (8, 18) such as to form a super junction structure by the pn-junction portion with the drift region (8, 18).

[C20] The semiconductor device (1A to 1L) according to any one of C17 to C19, wherein the drift region (8, 18) includes at least one type of trivalent element among aluminum, gallium, and indium, and the impurity region (19, 20) includes at least one among arsenic and antimony.

[C21] The semiconductor device (1A to 1L) according to any one of C1 to C20, wherein the drift region (8, 18) has a thickness belonging to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

[C22] The semiconductor device (1A to 1L) according to any one of C1 to C21, wherein the WBG semiconductor chip (2) includes carbon (C).

[C23] The semiconductor device (1A to 1L) according to any one of C1 to C22, wherein the WBG semiconductor chip (2) is constituted of an SiC chip (2).

[C24] The semiconductor device (1A to 1L) according to C23, wherein the SiC chip (2) is constituted of an SiC monocrystal that is a hexagonal crystal, and the main surface (3) is arranged along a c-plane of the SiC monocrystal and has an off angle (θ) of not more than 10° with respect to the c-plane.

[C25] The semiconductor device (1A to 1L) according to C24, wherein the off angle (θ) has an off direction (D) oriented along an a-axis direction of the SiC monocrystal, and the impurity region (19, 20) is formed as a band that extends along the a-axis direction in plan view.

[C26] The semiconductor device (1A to 1L) according to any one of C1 to C25, wherein the drift region (8, 18) is formed in an epitaxial layer.

[C27] The semiconductor device (1A to 1L) according to any one of C1 to C26, further comprising: a functional device (9) that is formed in the main surface (3).

[C28] The semiconductor device (1A to 1L) according to C27, wherein the functional device (9) includes a diode.

[C29] The semiconductor device (1A to 1L) according to C28, further comprising: an insulating film (22) that covers the main surface (3) such as to partially expose the main surface (3); a first main surface electrode (23) that is electrically connected to the main surface (3); and a second main surface electrode (24) that is formed on a surface (4) at an opposite side to the main surface (3).

[C30] The semiconductor device (1A to 1L) according to C29, wherein the insulating film (22) exposes the drift region (8, 18), and the first main surface electrode (23) forms a Schottky junction with the drift region (8, 18).

[C31] The semiconductor device (1A to 1L) according to C27, wherein the functional device (9) further includes a transistor.

[C32] The semiconductor device (1A to 1L) according to C31, further comprising: a channel (CH) that is formed in a surface layer portion of the drift region (8, 18); and a gate structure (37, 63, 84) that is formed on the main surface (3) and controls on/off of the channel (CH).

[C33] The semiconductor device (1A to 1L) according to C32, further comprising: a first main surface electrode (54, 70) that is arranged on the main surface (3) and is electrically connected to the gate structure (37, 63, 84); a second main surface electrode (57, 73) that is arranged on the main surface (3) and is electrically connected to the channel (CH); and a third main surface electrode (60, 75) that is formed on a surface (4) at an opposite side to the main surface (3).

[D1] A semiconductor device (1A to 1L) comprising: a WBG (wide band gap) semiconductor chip (2) that has a first main surface (3) at one side and a second main surface (4) at another side; a base region (6, 16) of a first conductivity type that is formed in a region inside the WBG semiconductor chip (2) at the second main surface (4) side, includes a first impurity of the first conductivity type, and has a first concentration (C1); a buffer region (7, 17) of the first conductivity type that is formed in a region inside the WBG semiconductor chip (2) at the first main surface (3) side with respect to the base region (6, 16), includes the first impurity, and has a concentration distribution that decreases from the first concentration (C1) to a second concentration (C2) with the base region (6, 16) as a starting point; a drift region (8, 18) of the first conductivity type that is formed in a region inside the WBG semiconductor chip (2) between the first main surface (3) and the buffer region (7, 17), includes the first impurity and a second impurity of the first conductivity type that differs from the first impurity, and has a concentration distribution that increases from the second concentration (C2) to a third concentration (C3) with the buffer region (7, 17) as a starting point; and a plurality of column regions (19, 20) of a second conductivity type that are formed inside the drift region (8, 18) such as to form a super junction structure with the drift region (8, 18).

[D2] The semiconductor device (1A to 1L) according to D1, wherein the column regions (19, 20) extend in a thickness direction such as to traverse an intermediate portion (MID) of the drift region (8, 18).

[D3] The semiconductor device (1A to 1L) according to D1 or D2, wherein the column regions (19, 20) are formed at intervals to the first main surface (3) side from a bottom portion of the drift region (8, 18).

[D4] The semiconductor device (1A to 1L) according to any one of D1 to D3, wherein the column regions (19, 20) have a concentration distribution that increases toward the first main surface (3) side.

[D5] The semiconductor device (1A to 1L) according to any one of D1 to D4, wherein the drift region (8, 18) includes a basal concentration (CA) due to the first impurity and an added concentration (CB) due to the second impurity.

[D6] The semiconductor device (1A to 1L) according to D5, wherein the drift region (8, 18) includes a first region (8a, 18a) that is formed separated from the first main surface (3) in a surface layer portion of the first main surface (3) and is constituted of the basal concentration (CA) and a second region (8b, 18b) that is formed in a region between the first main surface (3) and the first region (8a, 18a) and is constituted of the basal concentration (CA) and the added concentration (CB), and the column regions (19, 20) are formed inside the second region (8b, 18b) such as to form the super junction structure with the second region (8b, 18b).

[D7] The semiconductor device (1A to 1L) according to D6, wherein the column regions (19, 20) are formed inside the second region (8b, 18b) at an interval to the first main surface (3) side from the first region (8a, 18a).

[D8] The semiconductor device (1A to 1L) according to any one of D5 to D7, wherein the added concentration (CB) has a concentration distribution that increases toward the first main surface (3).

[D9] The semiconductor device (1A to 1L) according to any one of D5 to D8, wherein the basal concentration (CA) has a concentration distribution that is substantially constant in a thickness direction.

[D10] The semiconductor device (1A to 1L) according to any one of D1 to D9, wherein the first conductivity type is an n-type, and the second conductivity type is a p-type.

[D11] The semiconductor device (1A to 1L) according to D10, wherein the column regions (19, 20) include a trivalent element other than boron.

[D12] The semiconductor device (1A to 1L) according to D10 or D11, wherein the column regions (19, 20) include at least one type of trivalent element among aluminum, gallium, and indium.

[D13] The semiconductor device (1A to 1L) according to any one of D10 to D12, wherein the first impurity is a pentavalent element other than phosphorus, and the second impurity is a pentavalent element other than phosphorus.

[D14] The semiconductor device (1A to 1L) according to any one of D10 to D13, wherein the first impurity is nitrogen, and the second impurity is at least one among arsenic and antimony.

[D15] The semiconductor device (1A to 1L) according to any one of D1 to D14, wherein the base region (6, 16) has a first thickness, the buffer region (7, 17) has a second thickness that is less than the first thickness, and the drift region (8, 18) has a third thickness that is not less than the second thickness.

[D16] The semiconductor device (1A to 1L) according to D15, wherein the third thickness is less than the first thickness.

[D17] The semiconductor device (1A to 1L) according to D15 or D16, wherein the third thickness belongs to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

[D18] The semiconductor device (1A to 1L) according to any one of D1 to D17, wherein the WBG semiconductor chip (2) includes carbon (C).

[D19] The semiconductor device (1A to 1L) according to any one of D1 to D18, wherein the WBG semiconductor chip (2) is constituted of an SiC chip (2).

[D20] The semiconductor device (1A to 1L) according to D19, wherein the SiC chip (2) is constituted of an SiC monocrystal that is a hexagonal crystal, and the first main surface (3) is arranged along a c-plane of the SiC monocrystal and has an off angle (θ) of not more than 10° with respect to the c-plane.

[D21] The semiconductor device (1A to 1L) according to D20, wherein the off angle (θ) has an off direction (D) oriented along an a-axis direction of the SiC monocrystal, and the column regions (19, 20) are formed as bands that extend along the a-axis direction in plan view.

[D22] The semiconductor device (1A to 1L) according to any one of D1 to D21, wherein the base region (6, 16) is formed in a semiconductor substrate, the buffer region (7, 17) is formed in an epitaxial layer, and the drift region (8, 18) is formed in an epitaxial layer.

[D23] The semiconductor device (1A to 1L) according to any one of D1 to D22, further comprising: a functional device (9) that is formed in the first main surface (3).

[D24] The semiconductor device (1A to 1L) according to D23, wherein the functional device (9) includes at least one among a diode and a transistor.

[E1] A method for manufacturing a semiconductor device (1A to 1L) comprising: a step of preparing an epitaxial layer (14) of a first conductivity type that is constituted of a WBG (wide band gap) semiconductor monocrystal and is adjusted to be of low concentration; and a step of implanting an impurity of the first conductivity type into the epitaxial layer (14) by an ion implantation method to form a drift region (8, 18) of the first conductivity type having a target concentration.

[E2] The method for manufacturing a semiconductor device (1A to 1L) according to E1, wherein the epitaxial layer (14) that is adjusted to be of low concentration by a first impurity is prepared, and the drift region (8, 18) is formed by implanting a second impurity of the first conductivity type that differs from the first impurity into the epitaxial layer (14).

[E3] The method for manufacturing a semiconductor device (1A to 1L) according to E2, wherein the ion implantation method is a channeling implantation method of implanting the second impurity along a crystal axis (c-axis) of the WBG semiconductor monocrystal.

[E4] The method for manufacturing a semiconductor device (1A to 1L) according to E3, wherein the second impurity is implanted into the epitaxial layer (14) at an angle of not more than ±5° on the basis of the crystal axis (c-axis) of the WBG semiconductor monocrystal.

[E5] The method for manufacturing a semiconductor device (1A to 1L) according to any one of E1 to E4, further comprising: a step of implanting an impurity of a second conductivity type into the epitaxial layer (14) by an ion implantation method to form an impurity region (19, 20) of the second conductivity type that forms a pn-junction portion with the drift region (8, 18), after the step of forming the drift region (8, 18).

[E6] The method for manufacturing a semiconductor device (1A to 1L) according to E5, wherein the ion implantation method is a channeling implantation method of implanting the impurity of the second conductivity type along the crystal axis (c-axis) of the WBG semiconductor monocrystal.

[E7] The method for manufacturing a semiconductor device (1A to 1L) according to E6, wherein the impurity of the second conductivity type is implanted into the epitaxial layer (14) at an angle of not more than ±5° on the basis of the crystal axis (c-axis) of the WBG semiconductor monocrystal.

[E8] A method for manufacturing a semiconductor device (1A to 1L) comprising: a step of preparing an n-type epitaxial layer (14) that is constituted of a WBG (wide band gap) semiconductor monocrystal and is adjusted to be of low concentration by nitrogen that is a pentavalent element; and a step of implanting a pentavalent element other than nitrogen into the epitaxial layer (14) by an ion implantation method to form an n-type drift region (8, 18) having a target concentration.

[E9] The method for manufacturing a semiconductor device (1A to 1L) according to E8, wherein the ion implantation method is a channeling implantation method of implanting the pentavalent element along a crystal axis (c-axis) of the WBG semiconductor monocrystal.

[E10] The method for manufacturing a semiconductor device (1A to 1L) according to E8 or E9, wherein the drift region (8, 18) is formed by implanting the pentavalent element other than phosphorus.

[E11] The method for manufacturing a semiconductor device (1A to 1L) according to any one of E8 to E10, wherein the drift region (8, 18) is formed by implanting at least one type of the pentavalent element among arsenic and antimony.

[E12] The method for manufacturing a semiconductor device (1A to 1L) according to any one of E8 to E11, further comprising: a step of implanting a trivalent element into the epitaxial layer (14) by an ion implantation method to form a p-type column region (19, 20) that forms a pn-junction portion with the drift region (8, 18), after the step of forming the drift region (8, 18).

[E13] The method for manufacturing a semiconductor device (1A to 1L) according to E12, wherein the ion implantation method is a channeling implantation method of implanting the trivalent element along a crystal axis (c-axis) of the WBG semiconductor monocrystal.

[E14] A method for manufacturing a semiconductor device (1A to 1L) comprising: a step of preparing an epitaxial layer (14) that is constituted of a WBG (wide band gap) semiconductor monocrystal and includes an n-type drift region (8, 18); and a step of implanting a trivalent element other than boron into the epitaxial layer (14) by an ion implantation method to form a p-type impurity region (19, 20) that forms a pn-junction portion with the drift region (8, 18).

[E15] The method for manufacturing a semiconductor device (1A to 1L) according to E14, wherein the impurity region (19, 20) that forms a super junction structure with the drift region (8, 18) is formed.

[E16] The method for manufacturing a semiconductor device (1A to 1L) according to E14 or E15, wherein a plurality of the impurity regions (19, 20) are formed.

[E17] The method for manufacturing a semiconductor device (1A to 1L) according to any one of E14 to E16, wherein the ion implantation method is a channeling implantation method of implanting the trivalent element along a crystal axis (c-axis) of the WBG semiconductor monocrystal.

[E18] The method for manufacturing a semiconductor device (1A to 1L) according to any one of E14 to E17, wherein the impurity region (19, 20) is formed by implanting at least one type of the trivalent element among aluminum, gallium, and indium.

[E19] The method for manufacturing a semiconductor device (1A to 1L) according to any one of E1 to E18, wherein the WBG semiconductor monocrystal includes carbon (C).

[E20] The method for manufacturing a semiconductor device (1A to 1L) according to any one of E1 to E19, wherein the WBG semiconductor monocrystal is constituted of an SiC monocrystal.

[E21] The method for manufacturing a semiconductor device (1A to 1L) according to E20, wherein the epitaxial layer (14) having an off angle (θ) of not more than 10° with respect to the c-plane of the SiC monocrystal is prepared.

[E22] The method for manufacturing a semiconductor device (1A to 1L) according to E21, wherein the off angle (θ) has an off direction (D) that is oriented along an a-axis direction of the SiC monocrystal.

While preferred embodiments of the present invention were described in detail above, these are merely specific examples used to clarify the technical contents of the present invention and the present invention should not be interpreted as being limited to these specific examples and the scope of the present invention is limited by the appended claims.

### REFERENCE SIGNS LIST

1A SiC semiconductor device
1B SiC semiconductor device
1C SiC semiconductor device
1D SiC semiconductor device
1E SiC semiconductor device
1F SiC semiconductor device
1G SiC semiconductor device
1H SiC semiconductor device
1I SiC semiconductor device
1J SiC semiconductor device
1K SiC semiconductor device
1L SiC semiconductor device
2 SiC chip
3 first main surface
4 second main surface
6 n-type base region
7 n-type buffer region
8 n-type drift region
8a first region
8b second region
9 functional device
14 second SiC epitaxial layer
16 p-type base region
17 p-type buffer region
18 p-type drift region
18a first region
18b second region
19 column region (impurity region)
20 column region (impurity region)
22 insulating film
23 first main surface electrode
24 second main surface electrode
37 trench gate structure (gate structure)
54 gate main surface electrode (first main surface electrode)
57 source main surface electrode (second main surface electrode)
60 drain electrode (third main surface electrode)
63 trench gate structure (gate structure)
70 gate main surface electrode (first main surface electrode)
73 source main surface electrode (second main surface electrode)
75 drain electrode (third main surface electrode)
84 planar gate structure (gate structure)
C1 first concentration
C2 second concentration
C3 third concentration
CA basal concentration
CB added concentration
D off direction
θ off angle
MID intermediate portion of drift region

1. An SiC semiconductor device comprising:
an SiC chip that has a main surface; and
an n-type drift region that is formed in a surface layer portion of the main surface and has an impurity concentration adjusted by at least two types of pentavalent elements.

2. The SiC semiconductor device according to claim 1, wherein the drift region has an impurity concentration that is adjusted such as to increase toward the main surface.

3. The SiC semiconductor device according to claim 1, wherein the drift region has an impurity concentration adjusted by pentavalent elements other than phosphorus.

4. The SiC semiconductor device according to claim 1, wherein the drift region includes nitrogen as a pentavalent element and a pentavalent element other than nitrogen.

5. The SiC semiconductor device according to claim 1, wherein the drift region has a basal concentration due to a first impurity that is a pentavalent element and an added concentration due to a second impurity that is a pentavalent element other than the first impurity.

6. The SiC semiconductor device according to claim 5, wherein the first impurity is a pentavalent element other than phosphorus, and
the second impurity is a pentavalent element other than phosphorus.

7. The SiC semiconductor device according to claim 6, wherein the first impurity is nitrogen, and
the second impurity is at least one among arsenic and antimony.

8. The SiC semiconductor device according to claim 5, wherein the added concentration has a concentration distribution that increases toward the main surface.

9. The SiC semiconductor device according to claim 5, wherein the basal concentration has a concentration distribution that is substantially constant in a thickness direction.

10. An SiC semiconductor device comprising:
an SiC chip that has a main surface; and
a p-type drift region that is formed in a surface layer portion of the main surface and has an impurity concentration adjusted by a trivalent element other than boron.

11. The SiC semiconductor device according to claim 10, wherein the drift region has an impurity concentration that is adjusted such as to increase toward the main surface.

12. The SiC semiconductor device according to claim 10, wherein the drift region includes at least one type of trivalent element among aluminum, gallium, and indium.

13. The SiC semiconductor device according to claim 10, wherein the drift region has a basal concentration due to a first impurity that is a trivalent element and an added concentration due to a second impurity that is a trivalent element being the same as or different from the first impurity.

14. The SiC semiconductor device according to claim 13, wherein the first impurity is aluminum, and
the second impurity is at least one among aluminum, gallium, and indium.

15. The SiC semiconductor device according to claim 13, wherein the added concentration has a concentration distribution that increases toward the main surface.

16. The SiC semiconductor device according to claim 13, wherein the basal concentration has a concentration distribution that is substantially constant in a thickness direction.

17. The SiC semiconductor device according to claim 1, wherein the drift region has a thickness belonging to any one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

18. The SiC semiconductor device according to claim 1, wherein the SiC chip is constituted of an SiC monocrystal that is a hexagonal crystal, and
the main surface is arranged along a c-plane of the SiC monocrystal and has an off angle of not more than 10° with respect to the c-plane.

19. The SiC semiconductor device according to claim 18, wherein the off angle has an off direction oriented along an a-axis direction of the SiC monocrystal.

20. The SiC semiconductor device according to claim 1, wherein the drift region is formed in an SiC epitaxial layer.
